(19) United States
(12) Patent Application Publication
(10) Pub. No.: US 2023/0261786 A1
(43) Pub. Date: Aug. 17, 2023

(54) Systems and Methods for Transmitting Streaming Symbols using Instantaneous Encoding

(71) Applicant: California Institute of Technology, Pasadena, CA (US)

(72) Inventors: Nian Guo, Pasadena, CA (US); Victoria Kostina, Pasadena, CA (US)

(73) Assignee: California Institute of Technology, Pasadena, CA (US)

(21) Appl. No.: 18/164,462

(22) Filed: Feb. 3, 2023

Related U.S. Application Data
(60) Provisional application No. 63/306,185, filed on Feb. 3, 2022.

(51) Int. Cl. H04L 1/00; H03M 13/15

(52) U.S. Cl. CPC H04L 1/0057; H03M 13/1555

(57) ABSTRACT

Systems and methods for performing real-time feedback communication in accordance with various embodiments of the invention are disclosed. In many embodiments, instantaneous encoding is utilized for transmitting symbols from a streaming source over a DMC with feedback. In certain embodiments, instantaneous encoding is performed during the arriving period of the symbols. At time t, the encoder and the decoder calculate the priors of possible symbol sequences using the source distribution and the posteriors at time t−1. In a number of embodiments, the encoder and decoder then partition the evolving message alphabet into groups, so that the group priors are close to the capacity-achieving distribution. In contrast to the SED rule for symmetric binary-input channels, partitioning processes in accordance with several embodiments of the invention utilize group priors instead of group posteriors for the partitioning. In many embodiments, once the groups are partitioned, the encoder determines the index of the group that contains the true symbol sequence it received so far and uses the group index to determine the appropriate channel input.

### CROSS-REFERENCE TO RELATED APPLICATIONS

The present invention claims priority to U.S. Provisional Patent Application Ser. No. 63/306,185 entitled “Instantaneous Encoding Phase for Transmitting Streaming Symbols Over a DMC with Feedback” to Guo et al., filed Feb. 3, 2022, the disclosures of which is herein incorporated by reference in its entirety.

### STATEMENT OF FEDERALLY SPONSORED RESEARCH

This invention was made with government support under Grant No. CCF1751356 CCF1956386awarded by the National Science Foundation. The government has certain rights in the invention.

### FIELD OF THE INVENTION

The present invention generally relates to digital communication systems and more specifically to the joint source-channel coding of streaming data over a discrete memoryless channel.

### BACKGROUND

With the emergence of the Internet of Things, communication systems, such as those employed in distributed control and tracking scenarios, are becoming increasingly dynamic, interactive, and delay-sensitive. The source symbols in such real-time systems arrive at the encoder in a streaming fashion. For example, the height and the speed data of an unmanned aerial vehicle stream into the encoder in real time. An intriguing question is: what codes can transmit streaming data with both high reliability and low latency over a channel with feedback?

Classical posterior matching schemes can reliably transmit messages over a channel with feedback but under the assumption that the source sequence is fully accessible to the encoder before the transmission. One can simply buffer the arriving data into a block and then transmit the data block using a classical posterior hatching scheme. Intuitively, the buffer-then-transmit code is a good choice if the buffering time is negligibly short, i.e., if data packets arrive at the encoder at an extremely fast rate. However, if data packets arrive at the encoder steadily rather than in a burst, the buffer-then-transmit code becomes ill-suited due to the delay introduced by collecting data into a block before the transmission.

The term instantaneous encoding can be used to describe a system that starts transmitting as soon as the first message symbol arrives and incorporates new message symbols into the continuing transmission on the fly. In a similar mariner to posterior matching schemes, instantaneous encoding schemes can take advantage of full channel feedback.

Designing good channel block encoding schemes with feedback is a classical problem in information theory, since feedback, though unable to increase the capacity of a memoryless channel, can simplify the design of capacity-achieving codes and improve achievable delay-reliability trade-offs. The underlying principle behind capacity-achieving block encoding schemes with feedback, termed posterior matching, is to transmit a channel input that has two features. First, the channel input is independent of the past channel outputs representing the new information in the message that the decoder has not yet observed. Second, the probability distribution of the channel input is matched to the capacity-achieving one using the posterior of the message.

While asymptotically achieving the channel capacity can help achieve the best possible transmission rates in the limit of large delay, balancing the trade-off between delay and reliability can be critical for time-sensitive applications. The delay-reliability trade-off is often measured by a reliability function (a.k.a. optimal error exponent), which is defined as the maximum rate of the exponential decay of the error probability at a rate strictly below the channel capacity as the blocklength is taken to infinity.

A number of academic papers have proposed channel block encoding schemes that are structurally similar in that they have two phases. In the communication phase, the encoder matches the distribution of its output to the capacity-achieving input distribution, while aiming to increase the decoder's belief about the true message. In the confirmation phase, the encoder repeatedly transmits one of two symbols indicating whether or not the decoder's estimate at the end of the communication phase is correct. The code transmitted in the communication phase can be replaced by any non-feedback block channel code, provided that the error probability of the block code is less than a constant determined by the code rate as the blocklength goes to infinity.

Use of a two-phase code is not essential as is demonstrated by the MaxEJS code. The MaxEJS code searches for the deterministic encoding function that maximizes an extrinsic Jensen-Shannon (EJS) divergence at each time. Since the MaxEJS code has a double exponential complexity in the length of the message sequence k, for symmetric binary-input DMCs, a simplified encoding function referred to as the Small-Enough Difference (SED) rule has been proposed. The small-enough difference (SED) rule is a simplified encoding function, The SED encoder partitions the message alphabet into two groups such that the difference between group posteriors and the Bernoulli (½) capacity-achieving distribution is small. While the SED rule still has an exponential complexity in the length of the message, a systematic variable-length code for transmitting k bits over a binary symmetric channel (BSC) with feedback can be designed that has complexity O(k²). The complexity reduction can be realized by grouping messages with the same posterior.

While the messages in the channel block encoding schemes described above are equiprobably distributed on their respective alphabets, a JSCC reliability function for transmitting a non-equiprobable discrete-memoryless source (DMS) over a DMC can be determined. For fixed-length almost lossless coding without feedback, an achievability bound on JSCC reliability function can be derived, which indicates that JSCC leads to a strictly larger error exponent than separate source and channel coding in some cases. For variable-length loss coding with feedback, a JSCC excess-distortion reliability function can be derived under the assumption that 1 source symbol is transmitted per channel use on average. To achieve the excess-distortion reliability function, separate source and channel codes are used where: the source is compressed down to its rate-distortion function, and the compressed symbols are transmitted using the Y-I communication phase, while the Y-I confirmation phase is modified to compare the uncompressed source and its lossy estimate instead of the compressed symbol and the estimate thereof. Due to the modification, some channel coding errors bear no effect on the overall decoding error, and the overall decoding error is dominated bv the decoding error of the repetition code in the confirmation phase.

While most feedback coding schemes in the academic literature considered block encoding of a source whose outputs are accessible in their entirety before the transmission, several existing works considered instantaneous encoding of a streaming source. Several papers explore instantaneous (causal) encoding schemes for stabilizing a control system. The evolving system state can be considered as a streaming data source, where the observer instantaneously transmits information about the state to the controller, and the controller injects control signals into the plant. The anytime capacity at anytime reliability a can be defined as the maximum transmission rate R (nats per channel use) such that the decoding error of the first k R-nat symbols at time t decays as e^{-α(t-k)} for any k≤t. It has been suggested that codes that lead to an exponentially decaying error have a natural tree structure that tracks the state evolution over time. Assuming that the inter-arrival times of message bits are known by the decoder and that the channel is a BSC, an anytime code has been proposed that achieves a positive anytime reliability and for which a lower bound on the maximum rate that leads to an exponentially vanishing error probability can be derived. Instantaneous encoding schemes have also been studied in pure communication settings, where one may evaluate the error exponent, consider a streaming source with finite length, and allow non-periodic deterministic or random streaming times. It has been shown that instantaneous encoding of i.i.d. message symbols that arrive at the encoder at consecutive times for transmission over a binary erasure channel (BEC) with feedback can be formed in such a way that the zero-rate JSCC error exponent of erroneously decoding the k-th message symbol at time t for fixed k and t→∞. In addition, a causal encoding scheme has been designed for k<∞ streaming bits with a fixed arrival rate over a BSC, which simulations have demonstrated that the code rate approaches the channel capacity as the bit arrival rate approaches the transmission rate.

### SUMMARY OF THE INVENTION

Systems and methods for performing real-time feedback communication in accordance with various embodiments of the invention are disclosed. In many embodiments, instantaneous encoding is utilized for transmitting a sequence of k source symbols over a DMC with feedback. In certain embodiments, instantaneous encoding is performed during the arriving period of the symbols. At time t, the encoder and the decoder calculate the priors of possible symbol sequences using the source distribution and the posteriors at time t−1. In a number of embodiments, the encoder and decoder then partition the evolving message alphabet into groups, so that the group priors are close to the capacity-achieving distribution. In contrast to the SED rule for symmetric binary-input channels, the partitioning processes utilized in accordance with various embodiments of the invention can be applied to any DMC. Furthermore, partitioning processes in accordance with several embodiments of the invention utilize group priors instead of group posteriors for the partitioning. Using group priors can be beneficial, because when a new symbol arrives at time t, the posteriors at time t−1 are typically insufficient to describe the symbol sequences at time t. Feedback codes with block encoding only need to consider the posteriors, since block encoding implies that the priors at time t are equal to the posteriors at time t−1. In many embodiments, once the groups are partitioned, the encoder determines the index of the group that contains the true symbol sequence it received so far and applies randomization to match the distribution of the transmitted index to the capacity-achieving one.

For streaming symbols with an arriving rate greater than

$$\frac{1}{H} ( H ( {P}_{Y}^{*} ) - log \frac{1}{{p}_{max}} ) ,$$

it can be shown that preceding any code with block encoding that achieves the JSCC reliability function for a fully accessible source by an instantaneous encoding phase in accordance with an embodiment of the invention can enable the communication system to achieve the block encoding error exponent as if the encoder knew the entire source sequence before the transmission. Here H is a lower bound on the information in the streaming source and is equal to the source entropy rate if the source is information stable. H(P*_{Y}) is the entropy of the channel output distribution induced by the capacity-achieving channel input distribution, and pₘₐₓ is the maximum channel transition probability. Thus, surprisingly, the JSCC reliability function for streaming is equal to that for a fully accessible source. Furthermore, it can be shown via simulation that the reliability function gives a surprisingly good approximation to the delay-reliability tradeoffs attained by the JSCC reliability function-achieving codes in the ultra-short blocklength regime.

In the remote tracking and control scenarios, a single code can be utilized in accordance with various embodiments of the invention that enables a decoder to choose to decode any k symbols of a streaming source at any time t with an error probability that decays exponentially with the decoding delay (i.e., an anytime code). In a number of embodiments, the code is an instantaneous small-enough difference (SED) code. In many embodiments, an instantaneous SED code is utilized that is similar to the instantaneous encoding phase except that it continues the transmissions after the symbol arriving period, drops the randomization step, and specifies the group partitioning rule to be the instantaneous SED rule. In certain embodiments, the instantaneous smallest-difference rule can minimize the difference between the group priors and the capacity-achieving probabilities, whereas the instantaneous SED rule only drives their difference small enough. In contrast to the instantaneous encoding phase followed by a block encoding scheme, instantaneous SED codes in accordance with many embodiments of the invention only have one phase, namely, it follows the same transmission strategy at each time. For transmitting i.i.d. Bernoulli (½) bits that arrive at the encoder at consecutive times over a BSC(0.05), simulations of the instantaneous SED code show that the error probability of decoding the first k=[4:4:16] bits at times t∈[4, 64], t≥k, decreases exponentially with anytime reliability α≃0.172. This implies that a binary instantaneous SED code in accordance with an embodiment of the invention can be used to stabilize an unstable linear system with bounded noise. It can be shown that a sequence of instantaneous SED codes implemented in accordance with various embodiments of the invention and indexed by the length of the symbol sequence k can achieve the JSCC reliability function for streaming over a Gallager-symmetric binary-input DMC. This result is based on the finding that, after dropping the randomization step, the instantaneous encoding phase continues to achieve time JSCC reliability function when followed by a reliability function-achieving block encoding scheme, but at a cost of increasing the lower bound on the symbol arriving rate to

$$\frac{1}{log \frac{1}{{p}_{S , max}}} ( log \frac{1}{{p}_{min}} - log \frac{1}{{p}_{max}} ) .$$

Here, p_{S,max} is the maximum symbol arriving probability and pₘᵢₙ is the mininmum channel transit ion probability.

Since the size of the evolving source alphabet grows exponentially in time t, the complexities of the instantaneous encoding phase and the instantaneous SED code are expontential in time t. For source symbols that are equiprobably distributed, low-complexity algorithms can be utilized for both codes that can be referred to as type-based codes. The complexity reduction can be achieved by judiciously partitioning the evolving source alphabet into types in a number of embodiments, the cardinality of the partition is O(t), i.e., it is exponentially smaller than the size of the source alphabet. The type partitioning enables the encoder and the decoder to update the priors and the posteriors of the source sequences as well as to partition source sequences in terms of types rather than individual sequences. Since the prior and the posterior updates have a linear complexity in the number of types, and the type-based group partitioning rule has a log-linear complexity in the number of types due to type sorting, type-based codes in accordance with many embodiments of the invention only have a log-linear complexity O(t log t).

For the transmission over a degenerate DMC, i.e., a DMC whose transition matrix contains a zero, a number of embodiments utilize a code with instantaneous encoding that achieves zero error for all rates asymptotically below Shannon's JSCC limit. While feedback codes in most prior literature are designed for non-degenerate DMCs, (i.e., a DMC whose transition probability matrix has all positive entries), a channel code can be constructed for degenerate DMCs that achieves zero error for all rates asymptotically below the channel capacity. In a number of embodiments of the invention, the system uses a code, that extends these prior art codes to JSCC and to the streaming source. In certain embodiments, the code is divided into blocks, and each block includes a communication phase and a confirmation phase. The communication phase in the first block of this scheme uses a code with instantaneous encoding that can transmit reliably for all rates below Shannon's JSCC limit; the [symbol] -th communication phase transmits the uncompressed source sequence to avoid compression errors, and uses random coding to establish an analyzable probability distribution of the decoding time. In a number of embodiments, the confirmation phase is the same as that utilized within the prior art: the encoder repeatedly transmits a pre-selected symbol that never leads to channel output y if the decoder's estimate at the end of the communication phase is wrong, and transmits another symbol that can lead to y if the estimate is correct. The confirmation phases can rely on the degenerate nature of the channel to achieve zero error: receiving a y secures an error-free estimate of the source.

A real-time feedback communication system in accordance with an embodiment of the invention includes: an encoder configured to: receive a plurality of symbols from a streaming source; perform an instantaneous encoding of each symbol in the plurality of symbols to generate channel inputs, where the instantaneous encoding of each symbol in the plurality of symbols occurs before the arrival of the next symbol in the plurality of symbols; transmit the generated channel inputs via a communication channel; receive feedback with respect to each transmission; and determine source posteriors in response to the feedback received with respect to each transmission. In addition, performing the instantaneous encoding of each symbol in the plurality of symbols comprises: calculating source priors based upon feedback received with respect to a last transmission, where the source priors calculated by the encoder are calculated for all possible symbol sequences using a source distribution and the posteriors determined by the encoder in response to feedback received by the encoder with respect to the last transmission; partitioning a message alphabet into groups using a partitioning rule based upon the source priors calculated by the encoder; determining an index of one of the groups that contains a sequence corresponding to symbols from the plurality of symbols that have been received by the encoder up to that point in time; and forming a channel input based upon the determined index, Furthermore, the communication system also comprises a receiver configured to: receive channel outputs via the channel; transmit feedback in response to the received channel outputs; and decode message symbols based upon the received channel outputs. In addition, decoding each received message symbol comprises: before receiving a next channel output, calculating source priors based upon at least one previously received channel output, where the source priors ea culated by the decoder are calculated for all possible symbol sequences using thesource distribution and source posteriors determined by the decoder; partitioning the message alphabet into groups using the partitioning rule based upon the source priors calculated by the decoder; upon receipt of the next channel output, calculating updated source posteriors for all possible sequences of source symbols using the source priors calculated by the decoder and the next channel output; decoding a next received message symbol based upon the next channel output and the groups obtained by the decoder using the partitioning rule; and forming feedback for transmission to the encoder.

In a further embodiment, forming a channel input based upon the determined index of the group that contains the sequence corresponding to the symbols from the plurality of symbols received by the encoder up to that point in time comprises applying randomization to match a distribution formed based upon transmitted indexes to a capacity-achieving distribution.

In another embodiment, each generated channel input is independent of past channel outputs.

In another further embodiment, the channel is a discrete memoryless channel.

In still another embodiment, the channel is a degenerate discrete memoryless channel.

In a yet further embodiment, the partitioning rule partitions the message alphabet into groups so that the source priors of the groups satisfy a predetermined criterion based upon a known capacity-achieving distribution.

In yet another embodiment, the predetermined criterion minimizes a difference between the source priors of the groups and the known capacity-achieving distribution.

In a further embodiment again, the predetermined criterion causes the source priors of the groups to be within a predetermined threshold of the known capacity-achieving distribution.

In another embodiment again, partitioning, by the encoder, of the message alphabet into groups using the partitioning rule based upon the calculated priors includes partitioning the message alphabet using a greedy heuristic algorithm.

In a further additional embodiment, the partitioning rule is a type-based group partitioning rule that partitions the message alphabet based on types.

In another additional embodiment, decoding the message symbols from the channel outputs received via the channel further comprises using the partitioned groups to construct two sets by comparing the source priors of the groups with a known capacity-achieving distribution.

In a still yet further embodiment, decoding the message symbols from the channel outputs received via the channel further comprises determining probabilities for randomizing the channel output based upon the two sets.

In still yet another embodiment, each of the plurality of symbols is a data packet.

In a still further embodiment again, the decoder is further configured to learn a symbol arriving distribution online using past symbol arrival times.

In still another embodiment again, the source is a linear system and the decoder is part of a control system that is configured to provide control signals to the linear system.

In a yet further embodiment again, the encoder and the decoder utilize a common source of randomness that is used by the encoder to generate the channel inputs and by the decoder to decode message symbols.

In yet another embodiment again, the encoder is further configured to transmit the channel input formed based upon the determined index prior to the receipt of the next message symbol from the plurality of symbols by the encoder from the streaming source.

In a still further additional embodiment, the message alphabet is an evolving message alphabet.

An encoder in accordance with an embodiment of the invention is configured to: receive a plurality of symbols from a streaming source; perform an instantaneous encoding of each symbol in the plurality of symbols to generate channel inputs, where the instantaneous encoding of each symbol in the plurality of symbols occurs before the arrival of the next symbol in the plurality of symbols; transmit the generated channel inputs via a communication channel; receive feedback with respect to each transmission; and determine source posteriors in response to the feedback received with respect to each transmission. In addition, performing the instantaneous encoding of each symbol in the plurality of symbols comprises: calculating source priors based upon feedback received with respect to a last transmission, where the source priors are calculated for all possible symbol sequences using a source distribution and the posteriors determined by the encoder in response to feedback received by the encoder with respect to the last transmission; partitioning a message alphabet into groups using a partitioning rule based upon the source priors; determining an index of one of the groups that contains a sequence corresponding to symbols frons the plurality of symbols that have been received by the encoder up to that point in time; and forming a channel input based upon the determined index.

In a further embodiment, the partitioning rule partitions the message alphabet into groups so that the priors of the groups satisfy a predetermined criterion based upon a known capacity-achieving distribution.

A decoder in accordance with another embodiment of the invention is configured to: receive channel outputs via a channel; transmit feedback in response to the received channel outputs; and decode message symbols based upon the received channel outputs. In addition, decoding each received message symbol comprises: before receiving a next channel output, calculating source priors based upon at least one previously received channel output, where the source priors are calculated for all possible symbol sequences using the source distribution and source posteriors determined by the decoder; partitioning the message alphabet into groups using a partitioning rule based upon the source priors; upon receipt of the next channel output, calculating updated source posteriors for all possible sequences of source symbols using the source priors and the next channel output; decoding a next received message symbol based upon the next channel output and the groups obtained by the decoder using the partitioning rule; and forming feedback for transmission.

In a further embodiment, the partitioning rule partitions the message alphabet into groups so that the priors of the groups satisfy a predetermined criterion based upon a known capacity-achieving distribution.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The description and claims will be more fully understood with reference to the following figures and data graphs, which are presented as exemplary embodiinents of the invention and should not be construed as a complete recitation of the scope of the invention.

FIG. 1 illustrates a system for communicating over a DNIC, with feedback symbols received from a streaming source in accordance with an embodiment of the invention.

FIGS. 2A and 2B illustrate a fully accessible source and a streaming source.

FIG. 3A illustrates a non-generate DMC. FIG. 3B illustrates a degenerate DMC. FIG. 3C illustrates a DMC that is neither non-degenerate nor degenerate.

FIG. 4 conceptually illustrates an example of group partitioning and channel input randomization for a DMC based upon a uniform capacity-achieving distribution in accordance with an embodiment of the invention.

FIG. 5 is a chart, illustrating error probability of decoding the first, k symbols of a DSS at time t achieved by a type-based instantaneous SED code in accordance with an embodiment of the invention.

FIG. 6 illustrates a scalar linear system controlled over a noisy channel with noiseless feedback in accordance with an embodiment of the invention.

FIG. 7 conceptually illustrates a type-based code in accordance with an embodiment of the invention. FIGS. 7a, 7b, and 7c represent three types at time t, where each row reprsents a source sequence in the type.

FIG. 8 illustrates simulated performance of instantaneous encoding schemes implemented in accordance with various embodiments of the invention.

FIG. 9 illustrates the simulated performance of a type-based instantaneous SED code implemented in accordance with an embodiment of the invention.

FIG. 10 illustrates an algorithm for determining a set of probabilities in accordance with an embodiment of the invention.

### DETAILED DESCRIPTION

Turning now to the drawings, systems and methods for performing real-time feedback communication using instantaneous encoding of symbols from a streaming source in accordance with various embodiments of the invention are illustrated. In many embodiments, an instantaneous encoding process is utilized that involves calculating priors based upon received feedback. In certain embodiments, the priors are used to partition a message alphabet into groups using a partitioning rule. In several embodiments, the instantaneous encoding process involves determining the index of the group that contains the sequence of symbols received by the encoder up to that point in time and then using the index to determine a channel input. In many embodiments, randomization can be applied the determined index so that the distribution of the transmitted channel inputs matches a capacity-achieving distribution. As can readily be appreciated, the specific processes utilized to perform instantaneous encoding of symbols from streaming sources in accordance with various embodiments of the invention depends upon the requirements of specific applications.

In several embodiments, the instantaneous encoding systems and methods utilize a partitioning rule that minimizes the distance between the group priors and a capacity-achieving distribution. In a number of embodiments, a SED partitioning rule is utilized that partitions groups so that the group priors are within a threshold difference of the capacity-achieving distribution. In certain embodiments, a type-based partitioning rule is used. In many embodiments, the practical implementation of the type-based codes described herein can enable instantaneous encoding with log-linear complexity. As can readily be appreciated, the specific partitioning rule that is utilized is largely dependent upon the requirements of specific applications.

In several embodiments, a JSCC reliability function-achieving code with block encoding, (e.g., the MaxEJS code or the SED code), is preceded by an instantaneous encoding phase implemented in accordance, which enables the system to overcome the detrimental effect due to the streaming nature of the source and can enable the system to achieve the same error exponent as if the encoder knew the entire source sequence before the. transmission,

In several embodiments, the encoder uses a JSCC reliability function-achieving codes that enables the encoder to transmit k symbols of a streaming source and stop. Jr many embodiments, the encoder uses an instantaneous SED code that enables a decoder to choose the decoding time and the number of symbols to decode on the fly, in this configuration, a communication system can empirically attain a positive anytime reliability, thus it can be used to stabilize an unstable scalar linear system with bounded noise over a noisy channel.

### Notation

Before discussing real-time feedback communication systems in accordance with various embodiments of the invention in further detail, it is helpful to clarify the notation that is used herein.

log(·) is the natural logarithm. Notation X←Y reads “replace X by Y”. For any positive integer q, we denote [q] [symbol] {1, 2, . . . q}. We denote [q]^{k} the set of all q-ary sequences of length equal to k. For a possibly infinite sequence x={x₁, x₂, . . . }, we write xⁿ={x₁, x₂, . . . xₙ} to denote the vector of its first n elements, and we write {xₙ}ₙ₌ₙ_{₁}ⁿ^{₂}={xₙ_{₁}, xₙ_{₁}₊₁, . . . , xₙ_{₂}} to denote the vector formed by its n₁, n₁+1, . . . , n₂-th elements. For a sequence of random variables Xₖ, k=1, 2, . . . and a real number α∈ [symbol] , we write

$${X}_{k} {\to }^{i . p .} a$$

to denote that Xₖ converges to α in probability, i.e., lim_{k→∞} [symbol] [|Xₖ−α|≥ϵ]=0, ∀ϵ>0. For any set [symbol] , we denote by [symbol] (x) an indicator function that is equal to 1 if and only if x∈ [symbol] . For two positive functions f,g: [symbol] ₊→ [symbol] ₊, we write f(k)=o(k)) to denote

$${lim}_{k \to ∞} \frac{f ( k )}{g ( k )} = 0 ;$$

we write f(k)=O(g(k)) to denote

$$lim {sup}_{k \to ∞} \frac{f ( k )}{g ( k )} < ∞ ;$$

we write f(k)=Ω(g(k)) to denote

$$lim {inf}_{k \to ∞} \frac{f ( k )}{g ( k )} > 0.$$

Having defined the notation that is utilized below, a discussion of real-time feedback communication systems in accordance with various embodiments of the invention follows.

### Real-Time Feedback Communication Systems

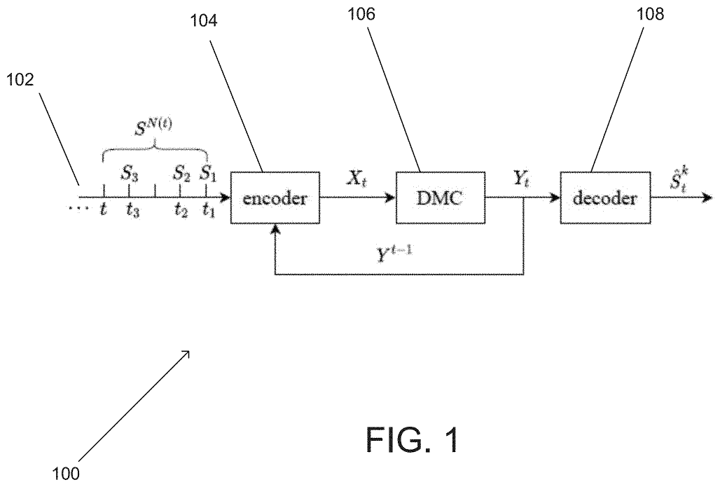

A real-time feedback communication system with a streaming source in accordance with an embodiment of the invention is illustrated in FIG. 1. The communication system 100 includes a streaming source 102 that provides a sequence of symbols to an encoder 104. The encoder 104 performs instantaneous encoding of the symbols and transmits signals via a DMC 106 with feedback to a decoder 108. The decoder receives a transmitted signal and performs a decoding process that outputs received symbols.

A streaming source 102 is a (Discrete Streaming Source) DSS when it emits a sequence of discrete source symbols Sₙ∈[q], n=1, 2, . . . , at times t₁≤t₂≤. . . , where symbol Sₙ that arrives at the encoder at time tₙ is distributed according to the source distribution

P_{S}_{ₙ}_{|S}ⁿ⁻¹,n=1,2 (1)

Throughout the discussion that follows, it is assumed that the entropy rate of the DSS

$$H {=}^{△} {lim}_{n \to ∞} \frac{H ( {S}^{n} )}{n} ( nats per symbol ) \qquad ( 2 )$$

is well-defined and positive; the first symbol S₁ arrives at the encoder at time t₁ [symbol] 1; both the encoder and the decoder know the symbol alphabet [q], the arrival times t₁, t₂, . . . , and the source distribution (1). The DSS reduces to the classical discrete source (DS) that is fully accessible to the encoder before the transmission if

tₙ=1, ∀n=1,2, (3)

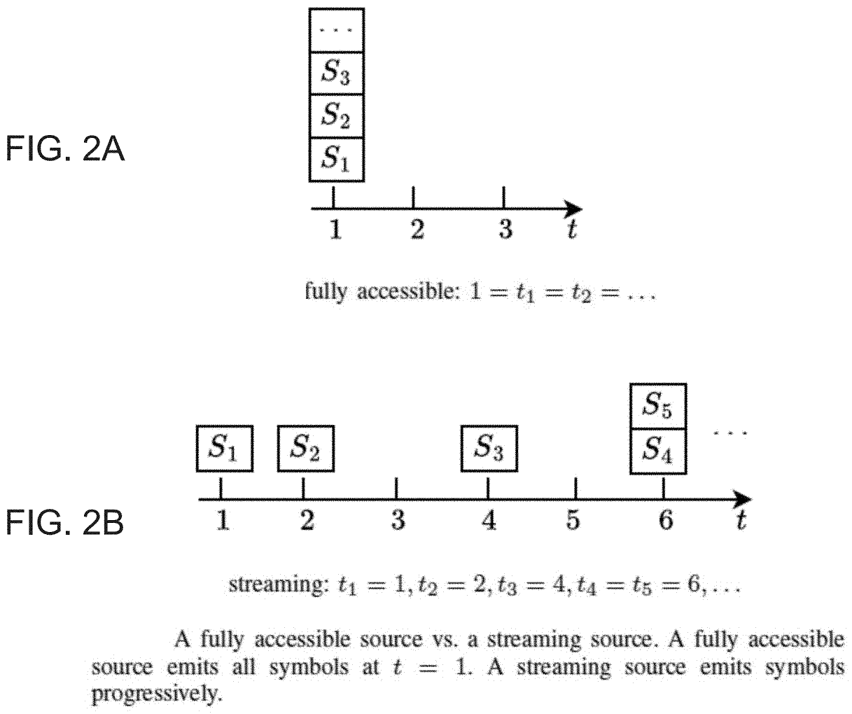

FIG. 2A displays a fully accessible source and FIG. 2B illustrates a streaming source. A fully accessible source emits all symbols at t=1. A streaming source emits symbols progressively.

Operationally, symbol Sₙ represents a data packet. We denote the number of symbols that the encoder has received by time t by

N(t) [symbol] max{n:tₙ≤t,n=1,2, . . . }. (4)

Given a DSS with symbol arriving times t₁, t₂, . . . , we denote its symbol arriving rate by, assuming that the limit exists

$$f {=}^{△} {lim}_{n \to ∞} \frac{n}{{t}_{n}} ( symbols per unit time ) ∈ [ 0 , ∞ ] . \qquad ( 5 )$$

The symbol arriving rate f=∞implies that the source symbols arrive at the encoder so frequently that the number of channel uses increases slower than the source length. For example, the DS (3) has f=∞. The symbol arriving rate f<∞ implies that the number of channel uses goes to infinity as the source length goes to infinity. For example, if one source symbol arrives at the encoder every λ≥1 channel uses, λ∈ [symbol] ₊, i.e.,

tₙ=λ(n−1)+1, (6)

then

$$f = \frac{1}{λ} . \qquad ( 7 )$$

We assume that the channel is a DMC with a single-letter transition probabilit distribution P_{Y|X}: [symbol] → [symbol] .

A DMC is non-degenerate if it satisfies

P_{Y|X}(y|x)>0,∀ₓ∈ [symbol] ,y∈ [symbol] . (8)

A DMC is degenerate if there exist y∈ [symbol] , x∈ [symbol] , x′∈ [symbol] , such that

P_{Y|X}(y|x)>0, (9a)

P_{Y|X}(y|x′)=0, (9b)

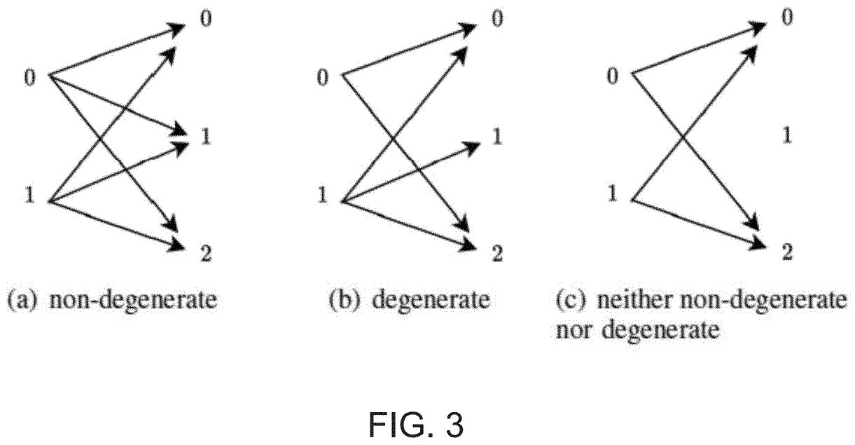

A BSC is a form of non-degenerate DMC. A BEC is a form of degenerate DMC. FIG. 3 displays examples of DMCs. In each channel, an arrow from channel input x∈{0, 1} to channel output y∈{0, 1, 2} signifies P_{Y|X}(y|x)>0. Channel (a) is a non-degenerate DMC that satisfies (8), Channel (b) is a degenerate DMC that satisfies (9) with y=1, x=1, x′=0, Channel (does not satisfy (8) (9) since y=1 is not reachable.

The capacity of a DMC can be denoted by

$$C {=}^{△} {max}_{{P}_{X}} I ( X ; Y ) , \qquad ( 10 )$$

and the maximum Kullback-Leibler (KL) divergence between its transition probabilities can be denoted by

$${C}_{1} {=}^{△} {max}_{x , {x}^{′} ∈ 𝒳} D ( {P}_{Y \vert X = x} ‖ {P}_{Y \vert X = {x}^{′}} ) . \qquad ( 11 )$$

Assumption (8) posits that C₁ (11) is finite.

A DMC is symmetric if the columns in its channel transition probability matrix can be partitioned so that within each partition, all rows are permutations of each other, and all columns are permutations of each other.

The symbol arriving rate (5) can be measured with a unit time equal to a channel use.

Codes that can be used to transmit a DSS over a DMC with feedback in accordance with various embodiments of the invention are discussed below. In many embodiments, the codes that are utilized are variable-length joint source-channel codes with feedback. In a number of embodiments, a code with instantaneous encoding is ilized. In several embodiments, a code with block encoding is utilized.

Variable-Length Joint Source-Channel Codes with Feedback

A code with instantaneous encoding designed to recover the first k symbols of a DSS at rate R symbols per channel use and error probability ϵ in accordance with an embodiment of the invention can be defined. For a (q, {tₙ}ₙ₌₁^{∞}) DSS and a DMC with a single-letter transition probability distribution P_{Y|X}: [symbol] → [symbol] , a (k, R, ϵ) code with instantaneous encoding can be defined as follows:

1. a sequence of (possibly randomized) encoding functions fₜ:[q]^{N(t)}× [symbol] → [symbol] , t=1, 2, . . . that the encoder uses to form the channel input

$${X}_{t} {=}^{△} {f}_{t} ( {S}^{N ( t )} , {Y}^{t - 1} ) ; \qquad ( 12 )$$

2. a sequence of decoding functions gₜ: [symbol] →[q]^{k}, t=1, 2, . . . that the decoder uses to form the estimate

Ŝₜ^{k} [symbol] gₜ(Y^{t}); (13)

3. a stopping time ηₖ adapted to the filtration generated by the channel output Y₁, Y₂, . . . that determines when the transmission stops and that satisfies

$$\frac{k}{𝔼 [ {η}_{k} ]} \geq R ( symbols per channel use ) , \qquad ( 14 )$$

$$ℙ [ {\hat{S}}_{{η}_{k}}^{k} \neq {S}^{k} ] \leq ϵ . \qquad ( 15 )$$

For any rate R>0, the minimum error probability achievable by rate-R codes with instantaneous encoding and message length k can be given by

ϵ*(k,R) [symbol] inf{ϵ:∃(k,R,ϵ) code with instantaneous encoding}, (16)

For transmitting a DSS over a non-degenerate DMC with noiseless feedback via a code with instantaneous encoding, the JSCC reliability function for streaming can be defined as

$$E ( R ) {=}^{△} {lim}_{k \to ∞} \frac{R}{k} log \frac{1}{ϵ ⋆ ( k , R )} . \qquad ( 17 )$$

If a DSS satisfies (3), i.e., a DS, a code with instantaneous encoding (i.e., causal code) reduces to a code with block encoding (i.e., non-causal code), and the JSCC reliability function for streaming (17) reduces to the JSCC reliability function for a fully accessible source.

E(R) (17) can be used to quantify the fundamental delay-reliability trade-off achieved by codes with instantaneous encoding. The reliability function is a classical performance metric that can be used to approximate that trade-off as

$$ϵ ≃ {e}^{- \frac{k}{R} E ( R )} .$$

Although this approximation ignores the subexponential terms, it can still shed light on the finite-blocklength performance.

Similar to classical codes with block encoding, a (k, R, ϵ) code with instantaneous encoding can be designed to recover only the first k symbols of a DSS, and E(R) (17) can be achieved by a sequence of codes with instantaneous encoding indexed by the length of the symbol sequence k as k→∞. A code with instantaneous encoding that decodes the first k symbols at a time t≥tₖ with an error probability that decays exponentially with delay t−tₖ can be defined, for all k and t. Because the decoding time and the number of symbols to decode can be chosen on the fly, this code can be referred to as an anytime code and can be used to stabilize an unstable linear systema with bounded noise over a noisy channel with feedback. Anytime codes can be formally defined as follows.

For a (q, {tₙ}ₙ₌₁^{∞}) DSS and a DMC with a single-letter transition probability distribution P_{Y|X}: [symbol] → [symbol] . A (κ, α) anytime code includes:

1. a sequence of (possibly randomized) encoding functions similar to those defined above;
2. a sequence of decoding functions g_{t,k}: [symbol] →[q]^{k} indexed both by the decoding time t and the length of the decoded symbol sequence k that, the decoder uses to form an estimate Ŝₜ^{k} [symbol] g_{t,k}(Y^{t}) of the first k symbols at time t.

For all k=1, 2, . . . , t=1, 2 . . . , t≥tₖ, the error probability of decoding the first k symbols at time t ideally must satisfy

[symbol]

[Ŝₜ^{k}≠S^{k}]≤ [symbol] (18)

for some κ, α∈ [symbol] ₊.

The exponentially decaying rate α of the error probability in (18) can be referred to as the anytime reliability.

### Instantaneous Encoding Phase

In a number of embodiments of the invention, the transmitter aims to transmit the first k source symbols of a DSS using an instantaneous encoding phase, using the encoding functions {fₜ}ₜ₌₁^{t}^{ₖ} described above. In several embodiments, the channel is a DNIC with a single-letter transition probability distribution P_{Y|X}: [symbol] → [symbol] and capacity-achieving distribution P*_{X}, and a (q, {tₙ}ₙ₌₁^{∞}) DSS with distribution (1). The following are functions of the channel outputs,

$${ρ}_{i} ( {Y}^{t} ) {=}^{Δ} {P}_{{S}^{N ( t )} \vert {Y}^{t}} ( i \vert {Y}^{t} ) , \qquad ( 19 )$$

$${θ}_{i} ( {Y}^{t - 1} ) {=}^{Δ} {P}_{{S}^{N ( t )} \vert {Y}^{t - 1}} ( i \vert {Y}^{t - 1} ) , \qquad ( 20 )$$

$${π}_{x} ( {Y}^{t - 1} ) {=}^{Δ} {\sum }_{i ∈ {𝒢}_{x} ( {Y}^{t - 1} )} {θ}_{i} ( {Y}^{t - 1} ) , \qquad ( 21 )$$

where ρᵢ(Y^{t}) and θᵢ(Y^{t}) are the posterior and the prior of source sequence i∈[q]^{N(t)}, respectively; πₓ(Y^{t-1}) is the prior of the group [symbol] (Y^{t-1}) corresponding to channel input x∈ [symbol] that we specify in (24) below. The probability distributions P_{S}_{^{N(t)}}_{|Y}_{^{t}} and P_{S}_{^{N(t)}}_{|Y}_{^{t−1}} can be determined by the code below.

Algorithm: The instantaneous encoding phase operates during times t=1, 2, . . . , tₖ.

At each time t, the encoder and the decoder first update the priors θᵢ(y^{t-1}) for all i∈[q]^{N(t)}. At symbol arriving times t=tₙ, n=1, 2, . . . , k the prior θᵢ(y^{t-1}), i∈[q]^{N(t)} is updated using the posterior ρᵢ_{^{N(t−1)}}(y^{t-1}) and the source distribution (1), i.e.,

θᵢ(y^{t-1})=P_{S}_{^{N(t)}}_{|S}_{^{N(t−1)}}(|i^{N(t-1)})ρᵢ_{^{N(t−1)}}(y^{t-1}), (22)

where i^{N(t-1)} is the length-N(t−1) prefix of sequence i.

At times in-between arrivals, i.e., at t∈(tₙ,tₙ₊₁), n=1, 2, . . . , k−1, the prior θᵢ(y^{t-1}) is equal to the posterior ρᵢ(y^{t-1}) for all i∈[q]^{N(t)}, i.e.,

θᵢ)(y^{t-1})=ρᵢ(y^{t-1}) (23)

At each time t, once the priors are updated, the encoder and the decoder partition the message alphabet [q]^{N(t)} into | [symbol] | disjoint groups [symbol] such that for all x∈ [symbol] , the group priors πₓ(y^{t-1}) are close to the capacity-achieving distribution P*_{X}(x); in a number of embodiments, the rule that is used to ensure closeness is

$${π}_{x} ( {y}^{t - 1} ) - {P}_{X}^{*} ( x ) \leq {min}_{i ∈ {𝒢}_{x} ( {y}^{t - 1} )} {θ}_{i} ( {y}^{t - 1} ) . \qquad ( 24 )$$

There always exists a partition [symbol] of [q]^{N(t)} that satisfies the partitioning rule (24), since a partition obtained by an algorithm such as (but not limited to) the greedy heuristic algorithm satisfies it.

Using the partition [symbol] , the encoder and the decoder can construct two sets by comparing the group priors [symbol] with the capacity-achieving distribution [symbol] :

[symbol]

(y^{t-}) [symbol] {x∈ [symbol] :πₓ(y^{t-1})≤P*_{X}(x)}, (25)

[symbol]

(y^{t-}) [symbol] {x∈ [symbol] :πₓ(y^{t-1})>P*_{X}(x)}, (26)

In a number of embodiments, the encoder and the decoder then randomize the channel input. In other embodiments, this randomization step is omitted. In the embodiments that do use randomization, the encoder and the decoder determine a set of probabilities [symbol] for randomizing the channel input, such that for all x̅∈ [symbol] (y^{t-1}),

x∈ [symbol] (y^{t-}), it holds that

$${π}_{\overline{x}} ( {y}^{t - 1} ) - {\sum }_{\underline{x} ∈ \underline{𝒳} ( {y}^{t - 1} )} {p}_{\overline{x} \to \underline{x}} = {P}_{X}^{*} ( \overline{x} ) , \qquad ( 27 )$$

$${π}_{\underline{x}} ( {y}^{t - 1} ) - {\sum }_{\overline{x} ∈ \overline{𝒳} ( {y}^{t - 1} )} {p}_{\overline{x} \to \underline{x}} = {P}_{X}^{*} ( \underline{x} ) . \qquad ( 28 )$$

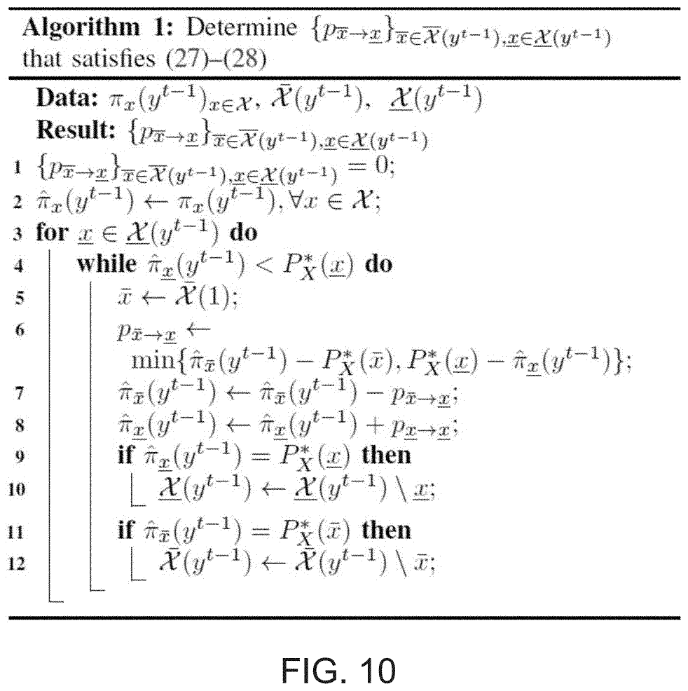

An algorithm for determining a set of probabilites [symbol] that satisfies (27)-(28) is illustrated in FIG. 10. The first element in set [symbol] (y^{t-1}) is denoted by [symbol] (1). The order of the elements in [symbol] (y^{t-1}) is irrelevant.

For every group [symbol] (y⁻¹) with x∈ [symbol] (y^{t-1)}, the algorithm illustrated in FIG. 10 goes through groups [symbol] (y^{t-1}) with x̅∈ [symbol] (y^{t-1}) to transfer probability p_{x̅→x} to [symbol] (y^{t-1}). The amount of probability p_{x̅→x} to transfer from [symbol] (y^{t-1}) to [symbol] (y^{t-1}) is the smallest of \hat{π}_{x̅}(y^{t-1})−P*_{X}(x̅) and P*_{X}(x)−\hat{π}ₓ(y^{t-1}). After the update, if the new prior \hat{π}_{x̅}(y^{t-1}) (or \hat{π}ₓ(y^{t-1})) is equal to its target value P*_{X}(x̅) (or P*_{X}(x) the corresponding group will be removed from the set [symbol] (y^{t-1}) (or [symbol] (y^{t-1})). In this way, [symbol] are determined. At the end of the algorithm, \hat{π}_{x̅}(y^{t-1}) and \hat{π}ₓ(y^{t-1}) indeed represent the left sides of (27) and (28), respectively.

As noted above, the use of randomization and the algorithm illustrated in FIG. 10 is optional and not utilized in man embodiments of the invention.

The output of the encoder is formed as follows. The encoder first determines the group that contains the sequence S^{N(t)} it received so far:

$${Z}_{t} {=}^{Δ} {\sum }_{x ∈ 𝒳} x {{}^{}}_{𝒢 x ( {y}^{t - 1} )} ( {S}^{N ( t )} ) . \qquad ( 29 )$$

In the embodiments that do not use randomization, Zₜ is transmitted directly into the channel. In the embodiments that use randomization, an extra randomness is added to Zₜ to form the channel input Xₜ as follows. The encoder outputs Xₜ according to

$${P}_{{X}_{t} \vert {Z}_{t} , {Y}^{t - 1}} ( x \vert z , {y}^{t - 1} ) = \{ \begin{matrix}\frac{{P}_{X}^{*} ( z )}{{π}_{z} ( {y}^{t - 1} )} , & if x = z , z ∈ \overline{𝒳} ( {y}^{t - 1} ) , \\ \frac{{p}_{z \to x}}{{π}_{z} ( {y}^{t - 1} )} , & if x ∈ \underline{𝒳} ( {y}^{t - 1} ) , z ∈ \overline{𝒳} ( {y}^{t - 1} ) \\ {\{ z \}}_{} ( x ) , & z ∈ \underline{𝒳} ( {y}^{t - 1} ) , \\ 0 , & otherwise .\end{matrix} \qquad ( 30 )$$

The decoder also knows the randomization distribution P_{X}_{ₜ}_{|Z}_{_{t,}}_{Y}_{^{t−1}} (30), since it knows group priors [symbol] (24), sets [symbol] (y^{t-1}) and [symbol] (y^{t-1}) (25) and probabilities [symbol] (27-28). Due to (25)-(30), the channel input distribution at time t=1, 2, . . . , tₖ, is equal to the capacity-achieving channel input distribution; i.e., for all y^{t-1∈} [symbol] ^{.}

P_{X}_{ₜ}_{|Y}_{^{t−1}}(x|y^{t-1})=P*_{X}(x). (31)

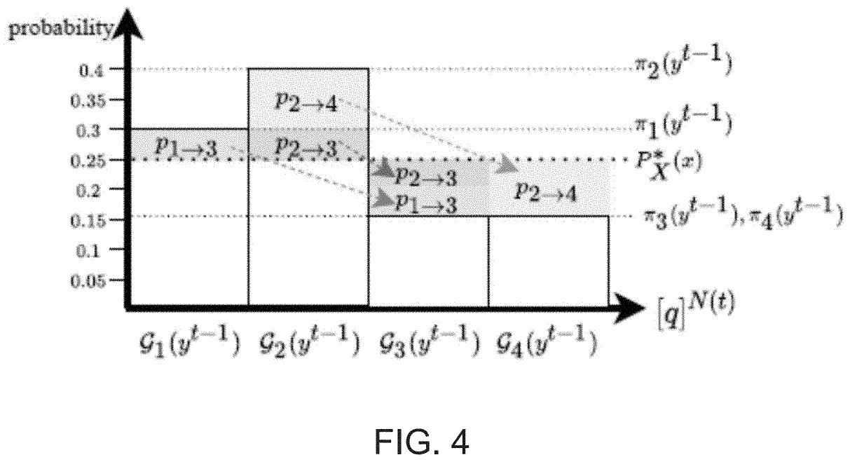

FIG. 4 protides an example of group partitioning and channel input randomization for a DMC with uniform capacity-achieving distribution P*_{X}(x)−0.25, [symbol] =[4]. The horizontal axis represents a partition of 4 groups. The vertical axis represents the prior probabilities of the groups. The source alphabet [q]^{N(t)} is partitioned into { [symbol] (y^{t-1})}_{x∈[4]} such that the partitioning rule (24) is satisfied. Groups [symbol] (y^{t-1}), x∈{1, 2} constitute [symbol] (y^{t-1}) (26) and groups [symbol] (y^{t-1}), x∈{3, 4} constitute [symbol] (y^{t-1}) (25). The probabilities {p_{x̅→x}}_{x̅∈{1,2},x∈{3,4}} (27)-(28) used to randomize transmitted group indices are colored. The randomization matches the probability of transmitting group index x∈[4] to P*_{X}(x).

Upon receiving the channel output Yₜ=yₜ at time t, the encoder and the decoder update the posteriors ρᵢ(y^{t}) for all possible sequences of source symbols i∈[q]^{N(t)} using the prior θᵢ(y^{t-1}), the channel output yₜ, and the randomization probability (30), i.e.,

$${ρ}_{i} ( {y}^{i} ) = \frac{{\sum }_{x ∈ 𝒳} {P}_{Y \vert X} ( {y}_{t} \vert x ) {P}_{{X}_{t} \vert {Z}_{t} , {Y}^{t - 1}} ( x \vert z ( i ) , {y}^{t - 1} )}{{P}_{Y}^{*} ( {y}_{t} )} {θ}_{i} ( {y}^{t - 1} ) , \qquad ( 32 )$$

where z(i) is the index of the group that contains sequence i, i.e., it is equal to the right side of (29) with S^{N(t)}←i; P*_{Y} is the channel output distribution induced by the capacity-achieving distribution P*_{X}; (32) holds due to (31) and the Markov chain Yₜ−Xₜ−(Zₜ,Yₜ₋₁)−S^{N(t)}.

It is important to appreciate that the randomization (25)-(30) of the instantaneous encoding phase is only used for analysis. Systems and methods in accordance with various embodiments of the invention can be utilized without performing the randomization step (25)-(30) in a process that involves transmitting the deterministic group index Zₜ (29), but at a cost of imposing stricter assumptions on the DSS.

From the perspective of encoding, the randomization (30) turns the encoding function ft into a stochastic kernel P_{X}_{ₜ}_{|S}_{^{N(t)}}_{,Y}_{^{t−1}}. From the perspective of the channel, the randomization P_{X}_{ₜ}_{|Z}_{ₜ}_{,Y}_{^{t−1}} (30) together with the DMC P_{Y|X} can be viewed as a cascaded DMC with channel input (Zₜ, Y^{t-1}). The randomness in (29) is not common with the decoder as it only needs to know the distribution P_{X}_{ₜ}_{|Z}_{ₜ}_{,Y}_{^{t−1}} to update posterior ρᵢ(y^{t}) in (32).

The complexity of the instantaneous encoding phase is O(q^{N(t)} log q^{N(t)}) if the classical greedy heuristic algorithm is used for group partitioning (24). A inure efficient algorithm that can be utilized in accordance with many embodiments of the invention to reduces the complexity down to O(t log t) is discussed below. While that algorithm can. be applied to any source distribution, it achieves optimum performance for equiprobably distributed source symbols.

### JSCC Reliability Function

In this section, a JSCC reliability function for streaming E(R) (17) using the instantaneous encoding phase introduced above is presented. For brevity, the maximum and the minimum channel transition probabilities of a DMC P_{Y|X}: [symbol] → [symbol] are denoted by

$${p}_{max} {=}^{Δ} {max}_{x ∈ 𝒳 , y ∈ 𝒴} {P}_{Y \vert X} ( y \vert x ) , \qquad ( 33 )$$

$${p}_{min} {=}^{Δ} {min}_{x ∈ 𝒳 , y ∈ 𝒴} {P}_{Y \vert X} ( y \vert x ) , \qquad ( 34 )$$

and the maximum symbol arriving probability of the DSS (1) is denoted by

$${p}_{S , max} {=}^{Δ} {max}_{n ∈ ℕ , s ∈ [ q ] , {s}^{′} ∈ {[ q ]}^{n - 1}} {P}_{{S}_{n} \vert {S}^{n - 1}} ( S \vert {S}^{′} ) . \qquad ( 35 )$$

For a non-degenerate DMC with capacity C (10), maximum KL divergence C₁ (11), and maximum channel transition probability pₘₐₓ (33) and a (q,{tₙ}ₙ₌₁^{∞}) DSS with entropy rate H>0 (2) and symbol arriving rate f (5), then, the JSCC reliability function for streaming (17) is equal to

$$\begin{matrix}E ( R ) = {C}_{1} ( 1 - \frac{H}{C} R ) , & 0 < R < \frac{C}{H} .\end{matrix} \qquad ( 36 )$$

The converse proof and the achievability proof for the above JSCC reliability function can be found in U.S. Provisional Patent Application Ser. No. 63/306,185, the relevant disclosure from which, including the converse proof and the achievability proof, is incorporated herein by reference in its entirety.

For any DSS with f=∞, including the DS (3), the buffer-then-transmit code for k source symbols can operate as follows, It waits until the k-th symbol arrives at time tₖ, and at times t≥tₖ+1, applies a JSCC code with block encoding for k symbols S^{k} of a (fully accessible) DS with prior P_{X}_{^{k}} (??) the buffer-then-transmit code achieves

$$E ( R ) \geq {C}_{1} ( 1 - ( \frac{H}{C} + \frac{1}{f} ) R ) , \qquad ( 37 )$$

which reduces to E(R) (361 for f=∞. Indeed, f=∞ means that the arrival time tₖ is negligible compared to the blocklength. The buffer-then-transmit code fails to achieve E(R) (36) if f<∞.

For any DSS with f<∞, the code with instantaneous encoding for k source symbols implements the instantaneous encoding phase at times t=1, 2, . . . , tₖ and operates as a JSCC code with block encoding for k symbols S^{k} of a (fully accessible) DS with prior P_{S}_{^{k}}_{|Y}_{^{t}}_{ₖ} at times t≥tₖ+1, where Y₁, . . . , Yₜ_{ₖ} are the channel outputs generated in the instantaneous encoding phase. If that JSCC code is reliability function-achieving, for example, the MaxEJS code (or the SED code for symmetric binary-input DMCs), then the concatenated code achieves E(R) (36).

Remarkably, it can be established that the JSCC reliability function for a streaming source can be equal to that for a fully accessible source. This is surprising as this means that revealing source symbols only causally to the encoder can in many instances have no detrimental effect on the reliability function.

While the instantaneous encoding phase can achieve E(R) (36) in fact, any coding strategy during the symbol arriving period that satisfies

$${lim}_{k \to ∞} \frac{I ( {S}^{k} ; {Y}^{{t}_{k}} )}{{t}_{k}} = C \qquad ( 38 )$$

achieves E(R) (36) when followed by a JSCC reliability function-achieving code with block encoding.

For equiprobably distributed q-ary source symbols that arrive at the encoder one by one at consecutive times t=1, 2, . . . , k and a symmetric q-input DMC, uncodec transmission during the symbol arriving period t=1, 2, . . . k satisfies (38) and thus constitutes an appropriate instantaneous encoding phase for that scenario. Furthermore, even if the instantaneous encoding phase drops the randomization (25)-(30) and transmits Zₜ (29) as the channel input, it can continue to satisfy the sufficient condition (38).

For a non-degenerate DMC with the maximum and the minimum channel transition probabilities pₘₐₓ and pₘᵢₙ, and for a (q,{tₙ}ₙ₌₁^{∞}) DSS with maximum symbol arriving probability p_{S,max}<1 and symbol arriving rate f<∞, if the DSS satisfies

(b′) the symbol arriving rate is large enough:

$$f > \frac{1}{log \frac{1}{{p}_{S , max}}} ( log \frac{1}{{p}_{min}} - log \frac{1}{{p}_{max}} ) , \qquad ( 39 )$$

then the instantaneous encoding phase that transmits the non-randors ized Zₜ (29) as the channel input at each time t=1, 2, . . . , tₖ satisfies (38), which means that it can achieve E(R) (36), the JSCC reliability function for streaming, when followed by a JSCC reliability function-achieving code with block encoding.

While various approaches to performing instantaneous encoding are described above, a variety of additional approaches that utilize alternative partitioning rules in accordance with various embodiments of the invention are discussed further below.

### Instantaneous SED Codes

Systems and methods in accordance with many embodiments of the invention utilize an SED code for a symmetric binary-input DMC. It can be shown by simulations that the instantaneous SED code empirically achieves a positive anytime reliability, and thus can be used to stabilize an unstable linear system with bounded noise over a noisy channel. Furthermore, it can be shown that if the instantaneous SED code is restricted to transmit the first k symbols of a DSS, a sequence of instantaneous SED codes indexed by the length of the symbol sequence k also achieves E(R) (36) for streaming over a symmetric binary-input DMC.

### Algorithm of the Instantaneous SED Code

In many embodiments, an instantaneous SET) code is utilized that is almost the same as the instantaneous encoding phase described above, expect that 1) it particularizes the partitioning rule (24) to the instantaneous SED rule in (40)-(41) (below; 2) its encoder does not randomize the channel input and transmits Zₜ (29) at each time t; and 3) it continues to operate after the symbol arriving period. Fixing a symmetric binary-input DMC P_{Y|X}:{0,1}→ [symbol] and fixing (q,{tₙ}ₙ₌₁^{∞}) DSS, the algorithm of the instantaneous SED code can be implemented as follows in several embodiments of the invention.

Algorithm: The Instantaneous SED Code Operates at Times t=1, 2, . . .

At each time t, the encoder and the decoder first update the priors θᵢ(y^{t-1}) for all possible sequences i∈[q]^{N(t)} that the source could have emitted by time t. If t=tₙ, n=1, 2, . . . , the prior is updated using (22); otherwise, the prior is equal to the posterior (23).

Once the priors are updated, the encoder and the decoder partition the source alphabet i∈[q]^{N(t)} into 2 disjoint groups { [symbol] }_{x∈{0,1}} according to the instantaneous SED rule, which says the following: if x, x′∈{0,1} satisfy

πₓ(y^{t-1})≥π_{x′}(y^{t-1}), (40)

then they must also satisfy

$${π}_{x} ( {y}^{t - 1} ) - {π}_{{x}^{′}} ( {y}^{t - 1} ) \leq {min}_{i ∈ {𝒢}_{x} ( {y}^{t - 1} )} {θ}_{i} ( {y}^{t - 1} ) . \qquad ( 41 )$$

There always exists a partition { [symbol] (y^{t-1})}_{∈{0,1}} that satisfies the instantaneous SED rule (40)-(41) since the partition that attains the smallest difference |π₀(y^{t-1})−π₁(y^{t-1})| can be shown to satisfy it.

Once the source alphabet is partitioned, the encoder can transmit the index Zₜ (29) of the group that contains the true source sequence S^{N(t)} as the channel input.

Upon receiving the channel output Yₜ=yₜ at time t, the encoder and the decoder update the posteriors ρᵢ(y^{t}) for all i∈[q]^{N(t)} using the priors θᵢ(y^{t-1}) and the channel output yₜ, i.e.,

$${ρ}_{i} ( {y}^{t - 1} ) = \frac{{P}_{Y \vert X} ( {y}_{t} \vert z ( i ) )}{{\sum }_{x ∈ 𝒳} {P}_{Y \vert X} ( y \vert x ) {π}_{x} ( {y}^{t - 1} )} {θ}_{i} ( {y}^{t - 1} ) , \qquad ( 42 )$$

where z(i) is the index of the group Mat contains sequence i, i.e, it is equal to the right side of (29) with S^{N(t)}←i.

The maximum a posteriori (MAP) decoder estimates the first k symbols at time t as

Ŝₜ^{k} [symbol] _{i∈[q]}_{^{k}}P_{S}_{^{k}}_{Y}_{ⁱ}(|Y^{t}). (43)

The group partitioning rule in x(40)-(41) can be referred to as the instantaneous small-enough difference (SED) rule since it reduces to the SED rule if the source is fully accessible to the encoder before the transmission. The instantaneous SED rule causes the difference between a group prior πₓ(y^{t-1}) and its corresponding capacity-achieving probability

$${P}_{X}^{*} ( x ) = \frac{1}{2} , x ∈ \{ 0 , 1 \}$$

to be bounded by the source prior on the right side of (41).

Even though the algorithm of the instantaneous SED code is presented for a DSS with deterministic symbol arriving times, it can be used to transmit a DSs with random, symbol arriving times. In that case, the number of symbols N(t) that have arrived by time t is a random variable, and the decoder only knows the symbol arriving distribution {P_{S}_{^{N(t)}}_{|S}_{^{N(t−1}})}ₜ₋₁^{∞}rather than the exact symbol arriving times. An instantaneous SED code can be used to transmit such a streaming source as long as the encoder and the decoder keep updating the source priors, partitioning the groups, and updating the posteriors at times t=1, 2, . . . for all possible source sequences that can arrive at the encoder by time t.

Systems and methods in accordance with embodiments of the invention can operate even when the the decoder knows neither the symbol arriving times nor the symbol arriving distribution. In this case, the decoder is configured to learn the symbol arriving distribution online using the past symbol arriving times.

### Instantaneous SED Codes are Anytime Codes

An instantaneous SED code can be shown to be an anytime code through numerical evidence: it empirically attains an error probability that decreases exponentially as (18).

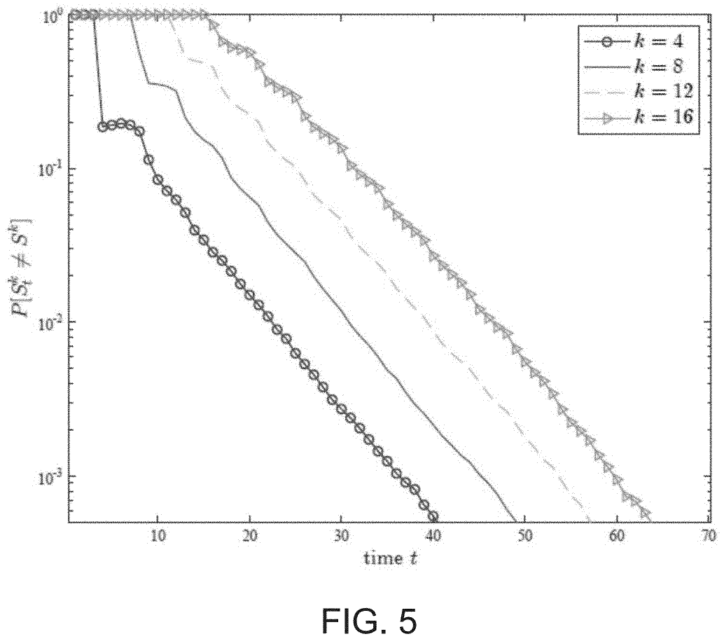

In FIG. 5, the error probability (18) of the instantaneous SED code is displayed, where the y-axis corresponds to the error probability of decoding the length-k; prefix of a DSS at time t (18). The error probability [symbol] [Ŝₜ^{k}≠S^{k}] of decoding the first k symbols of a DSS at time t achieved by the type-based instantaneous SET) code. The DSS emits a Bernoulli(½) bit, a times t=1, 2, . . . . The channel is a BSC(0.05).

At each time t, a process generates a Bernoulli(½) source it and a realization of a BSC(0.05), runs these experiments for 10⁵ trials, and obtains the error probability (18) by dividing the total number of errors by the total number of trials. To reduce the implementation complexity, a type-based version of the instantaneous SED code is simulated, which has a log-linear complexity. The type-based version is an approximation of the exact instantaneous SED code since it uses an approximating instantaneous SED rule and an approximating decoding rule to mimic the instantaneous SED rule (40)-(41) and the MAP decoder (43), respectively, however, it can perform remarkably close to the original instantaneous SED code.

The slope of the curves corresponds to the anytime reliability α (18) of the instantaneous SED code. The anytime reliability for the source and the channel in FIG. 5 is approximately equal to α≈0.172. The simulation results in FIG. 5 align with expectations: the error probability decays exponentially with delay t—k (18), implying that the instantaneous SEL) code is an anytime code.

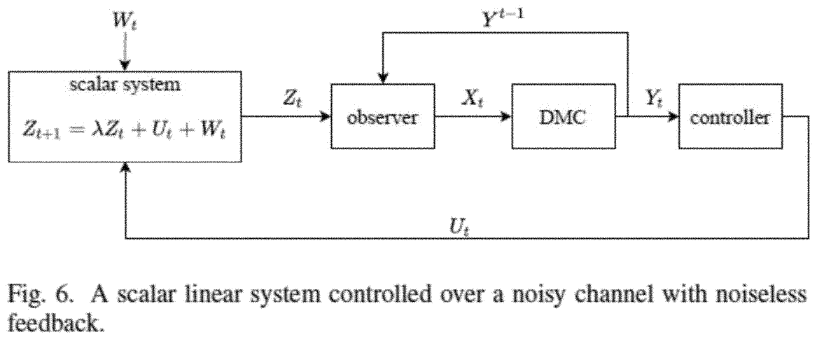

In a number of embodiments, an unstable scalar linear system can be stabilized by a system that utilizes instantaneous encoding including (but not limited to) the use of an instantaneous SED code. Consider the scalar linear system controlled over a noisy channel with noiseless feeqback that is displayed in FIG. 6, Zₜ₊₁=λZₜ°Uₜ+Wₜ, where λ>1, Zₜ is the real-valued state, Uₜ is the real-valued control signal,

$$\vert {W}_{t} \vert \leq \frac{Ω}{2}$$

is the bounded noise, and the initial state is Z₁ [symbol] 0. At time t, the observer uses the observed states Zₜ as well as the past channel feedback Y^{t-1} to form a channel input Xₜ; the controller uses the received channel outputs Yₜ to form a control signal Uₜ. For a (q,{tₙ}ₙ₌₁^{∞}) DSS that emits source symbols one by one at consecutive times tₙ=n, n=1, 2, . . . , the anytime rate of a (κ, α) anytime code can be defined as R_{any}=log q nats per channel use, e.g., for the DSS in FIG. 5, R_{any}=log 2; the α-anytime capacity C_{any}(α) is defined as the least upper bound on the anytime rates R_{any} such that the anytime reliability α is achievable. For such a DSS, it can be shown that the unstable scalar linear system with bounded noise in FIG. 6 can be stabilized so that η-th moment [symbol] [|Zₜ|^{η}] stays finite at all times, provided that C_{any}(α)>log λ, α>θ log λ. Thus, the instantaneous SED code can be used to stabilize the η-th moment of the unstable scalar linear system in FIG. 6 over a BSC(0.05) for any coefficient

$$λ < {e}^{min \{ {R}_{any} , \frac{α}{η} \}} \qquad ( 44 )$$

$$= min \{ 2 , {e}^{\frac{0.172}{η}} \} . \qquad ( 45 )$$

E.g., if η=2, then λ<1.09.

A control scheme that can stabilize the system in FIG. 6 employs an anytime code and operates as follows. At each time t, the observer computes an R_{any}-nat virtual control signal Ūₜ and acts as an anytime encoder to transmit Ūₜ as the t-th symbol of a DSS over a noisy channel with feedback. Here, Ūₜ controls a virtual state Z̅ₜ₊₁=λZ̅ₜ+Wₜ+Ūₜ, and is equal to the negative of the R_{any}-nat quantization of λZ̅ₜ. It ensures the boundedness of Z̅ₜ₊₁. Upon receiving the channel output, the controller acts as an anytime decoder to refresh its estimate Û̅ₜ^{t} of Ū^{t} and forms a control signal Uₜ that compensates the past estimation errors of the virtual control signals as if the plant {Zₛ}ₛ₌₁^{t+1} was controlled by [symbol] heretofore. As a result of applying Uₜ, the actual state Zₜ₊₁ is forced close to the bounded virtual state Z̅ₜ₊₁ with the difference |Zₜ₊₁−Z̅ₜ₊₁| governed by the difference between Ūₜ^{t} and [symbol] . The exponentially decaying with t−k error probability of decoding Ūₜ^{k} achieved by the anytime code together with the bounded Z̅ₜ₊₁ ensures a finite [symbol] [|Zₜ₊₁|^{η}]. In fact, the full feedback channel in FIG. 6 can be replaced by a channel that only feeds the control signal from the controller to the observer, since Zₜ, Zₜ₋₁, Uₜ₋₁ suffice to compute and thereby to compute Ūₜ at each time t.

As verified by the simulations in FIG. 5, the instantaneous SED code can achieve a positive anytime reliability.

### Instantaneous SED Code Achieves E(R)

The instantaneous SED codes described above can be restricted to transmit only the first it source symbols of a DSS, so that a sequence of instantaneous SED codes can be indexed by the length of the symbol sequence k. It can then be shown that the code sequence achieves the JSCC reliability function (36) for streaming over a symmetric binary-input DMC as k→∞.

The instantaneous SED code can be restricted to transmit the first k symbols of a (q,{tₙ}ₙ₌₁^{∞}) DSS as follows.
1)The alphabet [q]^{N(t)} that contains all possible sequences that could have arrived by time t is replaced by the alphabet [q]^{min{N(t)k}} that stops evolving and reduces to [q]^{k} after all k symbols arrive at time tₖ. As a consequence, for t≥tₖ+1 and all i∈[q]^{k}, the priors θᵢ(y^{t-1}) are equal to the corresponding posteriors ρᵢ(y^{t-1}), the encoder and the decoder partition [q]^{k} to obtain { [symbol] (y^{t-1})}_{x∈{0,1}}, the encoder transmits the index of the group that contains S^{k}, and only the posteriors ρᵢ(y^{t}) are updated.
2) The transmission is stopped and the MAP estimate (43) of S^{k} is produced at the stopping time

$${η}_{k} {=}^{Δ} min \{ t : {max}_{i ∈ {[ q ]}^{k}} {P}_{{S}^{k} \vert {Y}^{t}} ( i \vert {Y}^{t} ) \geq 1 - ϵ \} , ϵ ∈ ( 0 , 1 ) . \qquad ( 46 )$$

The MAP decoder (43) together with the stopping rule (46) can be utilized to enforce the error constraint in (15), since the MAP decoder (43) implies [symbol] [Ŝ_{η}_{ₖ}^{k}=S^{k}]= [symbol] [ [symbol] [ [symbol] {Ŝ_{η}_{ₖ}^{k}}(S^{k})|Y^{η}^{ₖ}]]= [symbol] [max_{i∈[q]}_{^{k}}P_{S}_{^{k}}_{|Y}_{^{η}}ₖ(i|Y^{η}^{ₖ})], which is lower bounded by 1−ϵ due to the stopping time (46).

As discussed above, a JSCC reliability function-achieving code with instantaneous encoding can be obtained by preceding a JSCC reliability function-achieving code with block encoding by an ins,a,ntaneous encoding phase that satisfies (38).

Low-Complexity Codes with Instantaneous Encoding

Type-based algorithms for the instantaneous encoding phase are described above, for the instantaneous SET) code as an anytime code, and for the instantaneous SED code restricted to transmit k symbols only. The type-based instantaneous encoding phase is the exact phase, whereas the type-based instantaneous SED codes are approximations of the original codes. Type-based codes that are discussed below and can be utilized by communication systems in accordance with various embodiments of the invention have a log-linear complexity O(t log t) in time t.

In a number of embodiments, it is assumed that the source symbols of the DSS are equiprobably distributed, i.e., the source distribution (1) satisfies

$${P}_{{S}_{n} \vert {S}^{n - 1}} ( a \vert b ) = \frac{1}{q} , \qquad ( 47 )$$

for all a|[q], b|[q]ⁿ⁻¹, n=1, 2, . . . Note that the algorithms will continue to apply even if the source distribution does not satisfy (47); in that case, optimality of the resulting codes cannot be expected, but we can still expect reasonable performance in practice.

In these type-based codes, the evolving source alphabet is judiciously divided into disjoint sets that can be called types, so that the source sequences in each type share the same prior and the same posterior. Here, the same prior is guaranteed by the equiprobably distributed symbols (47), and the same posterior is guaranteed by moving a whole type to a group during the group partitioning process (see step (iii) below). A.s a consequence of classifying source sequences into types, the prior update, the group partitioning, and the posterior update can be implemented in terms of types rather than individual source sequences, which can result in an exponential reduction of complexity.

A sequence of types can be denoted by [symbol] , [symbol] , . . . . The notation is slightly abused to denote by [symbol] (Y^{t-1}) and [symbol] (Y^{t}) the prior and the posterior of a single source sequence in type [symbol] at timet rather than the prior and the posterior of the whole type. In many embodiments, the type-based code is utilized. in a system that operates in combination with a (q,{tₙ}ₙ₌₁^{∞}) DSS that satisfies (47) and over a DMC with a single-letter transition probability P_{Y|X}: [symbol] → [symbol] .

### Type-Based Instantaneous Encoding Phase

The type-based instantaneous encoding phase can operate at times t=1, 2, . . . tₖ, where k is the number of source symbols of a DSS that it is desired to transmit.
(i) Type update: At each time t, the algorithm first updates the types. At t=1, the algorithm is initialized with one type [symbol] [q]^{N(1)}. At t=tₙ, n=2, . . . , k, the algorithm updates all the existing types by appending every sequence in [q]^{N(t)-N(t-1)} to every sequence in the type. After the update, the length of the source sequences in each type is equal to N(t); the cardinality of each type is multiplied by [q]^{N(t)-N(t-1)}; the total number of ts remains unchanged. At t≠tₙ, n=1, 2, . . . , k, the algorithm does not update the types.
(ii) Prior update: Once the types are updated, the algorithm can proceed to update the prior of the source sequences in each existing type. The prior [symbol] (y^{t-1}), j=1, 2, . . . of the source sequences in type [symbol] is fully determined by (22) with ηᵢ(y^{t-1})← [symbol] (y^{t-1}),

$${P}_{{S}^{N ( t )} \vert {S}^{N ( t - 1 )}} ( \cdot \vert \cdot ) ← {( \frac{1}{q} )}^{N ( t ) - N ( t - 1 )} ,$$

and ρᵢN(t−1)(y^{t-1})← [symbol] (y^{t-1}). If the types are not updated, the priors are equal to the posteriors, i.e., [symbol] (y^{t-1})← [symbol] (y^{t-1}), j=1, 2, . . .
(iii) Group partitioning: Using all the existing types and their priors, the algorithm can determine a partition [symbol] that satisfies the partitioning rule (24) via a type-based greedy heuristic algorithm. It operates as follows. It initializes all the groups [symbol] by empty sets and initializes the group priors [symbol] by zeros. It forms a queue by sorting all the existing types according to priors [symbol] (y^{t-1}), j=1, 2, . . . in a descending order. It moves the types in the queue one by one to one of the groups [symbol] . Before each move, it first determines a group [symbol] (y^{t-1}) whose current prior π_{x*}(y^{t-1}) has the largest gap to the corresponding capacity-achieving probability P*_{X}(x*),

$${x}^{*} {=}^{Δ} {argmax}_{x ∈ χ} {P}_{X}^{*} ( x ) - {π}_{x} ( {y}^{t - 1} ) . \qquad ( 48 )$$

Suppose the first type in the sorted queue,i.e. the type whose sequences have the largest prior, is [symbol] . It then proceeds to determine the number of sequences that are moved from type [symbol] to group [symbol] (y^{t-1}) by calculating

$$n {=}^{Δ} ⌈ \frac{{P}_{X}^{*} ( {x}^{*} ) - {π}_{{x}^{*}} ( {y}^{t - 1} )}{{θ}_{{S}_{j}} ( {y}^{t - 1} )} ⌉ . \qquad ( 49 )$$

If n≥| [symbol] |, then it moves the whole type [symbol] to group [symbol] (y^{t-1}); otherwise, it splits [symbol] into two types by keeping the smallest or the largest n consecutive (in lexicographic order) sequences in [symbol] and transferring the rest into a new type, and it moves type [symbol] to group [symbol] (y^{t-1}) and moves the new type to the beginning of the queue. This step can result in all sequences in a type being consecutive. Thus, it is sufficient to store two sequences, one with the smallest and one with the largest lexicographic orders, in a type to fully specify that type. It updates the prior π_{x*}(y^{t-1}) after each move.
(iv) Randomization: in some embodiments, the type-based instantaneous encoding algorithm implements the randomization in (25)-(30) with respect to a partition [symbol] . In other embodiments, the randomization step is dropped.
(v) Posterior update: Upon receiving the channel output Yₜ=yₜ, the algorithm updates the posterior of the source sequences in each existing type. The posterior ρ [symbol] (y^{t}), j=1, 2, . . . of the source sequences in type [symbol] is fully determined by (32) with ρᵢ(y^{t})←ρ [symbol] (y^{t}), θᵢ(y^{t-1})← [symbol] (y^{t-1}).

Using (49), it can be concluded that the type-based greedy heuristic algorithm achieves (24).

It can also be shown that the complexity of the type-based instantaneous encoding phase is log-linear O(t log t) at times t=1, 2, . . . , tₖ. In order to establish the complexity, it must first be shown that the number of types grows linea O(t). Since the type update in step (i) does not add new types, the number of types increases only due to the split of types during group partitioning in step (iii). At most | [symbol] | types are split at each time. This is because the ceiling in (49) ensures that the group that receives the it sequences from a split type will have a group prior no smaller than the corresponding capacity-achieving probability, thus the group will no longer be the solution to the maximization problem (48) and will not cause the split of other types. The complexity of each step of the algorithm can be analyzed. Step (i) (type update) has a linear complexity in the number of types, i.e., O(t). This is because the methods of updating: and splitting a type in steps (i) and (iii) causes the sequences in any type to be consecutive, thus it is sufficient to store the starting and the ending sequences in each type to fully specify all the sequences in that type. As a result, updating a type is equivalent to updating the starting and the ending sequences of that type. Step (ii) (prior update) and step (v) (posterior update) have a linear complexity in the number of types, i.e., O(t). Step (iii) (group partitioning) has a log-linear complexity in the number of types due to type sorting, i.e., O(t log t). This is because the average complexity of sorting a sequence of numbers is typically log-linear in the size of the sequence. Step (iv) (randomization) has complexity O(1) due to determining [symbol] in (27)-(28).

### Type-Based Instantaneous SED Codes

In a number of embodiments, a type-based anytime instantaneous SED code is utilized for a symmetric binary-input DMC that operates at times t=1, 2, . . . :
(i′) Type update: At each time t, the algorithm updates types as in step (1) with k=∞.
(ii′) Prior update: The algorithm updates the prior of the source sequences in each existing type as in step (ii) with k=∞.
(iii′) Group partitioning: Using all the existing types and their priors, the algorithm determines a partition { [symbol] (y^{t-1})}_{x∈{0,1}} using an approximating instantaneous SED rule that mimics the exact rule in (40)-(41) as follows. It forms a queue by sorting all the existing types according to priors [symbol] (y^{t-1}), j=1, 2, . . . in a descending order. It moves the types in the queue one by one to [symbol] (y^{t-1}) until π₀(y^{t-1})≥P*_{X}(0)=0.5 for the first time. Suppose the last type moved to [symbol] (y^{t-1}) is [symbol] . To make the group priors more even, it then calculates the number of sequences n to be moved away from [symbol] as

$$n {=}^{Δ} n ∈ \{ n , \overline{n} \} \vert ( {π}_{0} ( {y}^{t - 1} ) - n {θ}_{{𝒮}_{j}} ( {y}^{t - 1} ) ) - ( {π}_{1} ( {y}^{t - 1} ) + n {θ}_{{𝒮}_{j}} ( {y}^{t - 1} ) ) \vert , \qquad ( 50 a )$$

$$\underline{n} {=}^{Δ} ⌊ \frac{{π}_{0} ( {y}^{t - 1} ) - 0.5}{{θ}_{{𝒮}_{j}} ( {y}^{t - 1} )} ⌋ , \qquad ( 50 b )$$

$$\overline{n} {=}^{Δ} ⌈ \frac{{π}_{0} ( {y}^{t - 1} ) - 0.5}{{θ}_{{𝒮}_{j}} ( {y}^{t - 1} )} ⌉ . \qquad ( 50 c )$$

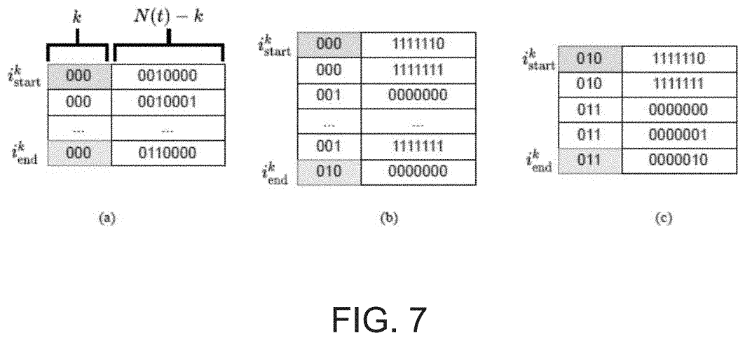

It splits [symbol] into two types bye transferring the first or the last n (50a) lexicographically ordered sequences in [symbol] to a new type. It moves the new type and all the remaining types in the queue to [symbol] (y^{t-1}).
(iv′) The randomization step in (iv) is dropped.
(v′) Posterior update: The algorithm updates the posteriors of the source sequences in each existing type. The posterior [symbol] (y^{t-1}), j−1, 2, . . . , is fully determined by (42) with ρᵢ(y^{t})← [symbol] (y^{t}), θᵢ(y^{t-1})← [symbol] (y^{t-1}).
(vi′) Decoding at time t: To decode the first k symbols at time t, here k can be any integer that satisfies tₖ≤t, the algorithm first finds the type whose source sequences have the largest posterior. Their, it searches for the most probable length-k prefix in that type by relying on the fact that sequences in the same type share the same posterior; thus, the prefix shared by the maximum number of sequences is the most probable one. Namely, the algorithm extracts the length-k prefixes of the starting and the ending sequences, denoted by iₛₜₐᵣₜ^{k} and i_{end}^{k}, respectively. If iₛₜₐᵣₜ^{k}=i_{end}^{k} (FIG. 7-a), then the decoder outputs Ŝₜ^{k}=iₛₜₐᵣₜ^{k}. If iₛₜₐᵣₜ^{k} and i_{end}^{k} are not lexicographically consecutive (FIG. 7-b), then the decoder outputs a length-k prefix in between the two prefixes. If iₛₜₐᵣₜ^{k} and i_{end}^{k} are lexicographically consecutive (FIG. 7-c), then the algorithm computes the number of sequences in the type that have prefix iₛₜₐᵣₜ^{k} and the number of sequences in the type that have prefix i_{end}^{k} using the last N(t)−k symbols of the starting and the ending sequences; the decoder outputs the prefix that is shared by more source sequences.

Referring to FIGS. 7-a through 7-c, tables (a), (b), (c) represent three types at time t. Each row represents a source sequence in the type. The first row and the last row in each type represent the starting sequence and the ending sequence in that type, respectively. The first column represents the length-k prefix of sequences in the type. The source sequences in a type are lexicographically consecutive due to the methods of updating and splitting a type in steps (i′) and (iii′). In (a), since iₛₜₐᵣₜ^{k}=i_{end}^{k}=000, the most probable sequence is 000. In (b), since iₛₜₐᵣₜ^{k}=000 and i_{end}^{k}=010 are not lexicographically consecutive, the most probable prefix is 001. In (c), since iₛₜₐᵣₜ^{k}=010 and i_{end}^{k}=011 are lexicographically consecutive, the number of sequences with prefix iₛₜₐᵣₜ^{k} can be computed by subtracting 1111110, the last N(t)−k symbols of the starting sequence, from 1111111 and adding 1; the number of sequences with prefix i_{end}^{k} is equal to the last N(t)−k symbols of the ending sequence plus 1. Since (c) contains more sequences with prefix 011, this is the most probable prefix.

The complexity of the type-based anytime instantaneous SED code is O(t log t). Similar to the type-based instantaneous encoding phase discussed above, the number of types grows linearly with time t since the number of types increases only if a type is split in step (iii′) and at most 1 type is spilt at each time t. The complexities of steps (i′), (ii′), (v′) are all linear in the number of types O(t). The complexity of step (iii′) is log-linear in the number of types O(t log t) due to sorting the types. Since the sequences in a type are lexicographically consecutive due to the updating and the splitting methods in steps (i′) and (iii′), it suffices to use the starting and the ending sequences in a type to determine the most probable prefix in that type. Thus, the complexity of step (vi′) is linear in the number of types due to searching for the type whose sequences have the largest posterior.

Restricting the type-based anytime instantaneous SED code described above to transmit only the first k symbols of a DSS is equivalent to implementing steps (i), (ii), (iii′), (v) one by one, and performing decoding as follows.
(vi″) Decoding and stopping: If there exists a type [symbol] that satisfies [symbol] (y^{t})≥1−ϵ and contains a source sequence of length k, then the decoder stops and outputs a sequence in that type as the estimate Ŝ_{η}_{ₖ}^{k}.

The complexity of the type-based instantaneous SED code for transmitting k symbols remains log linear, O(t log t), since the complexity of step (vi″) is O(t) due to searching for the type that satisfies the requirements.

While the type-based instantaneous enc Odin phase described above is the exact algorithm of the instantaneous encoding phase, the type-based anytime instantaneous SED code and the type-based instantaneous SED code for transmitting k symbols are approximations of the algorithms described above due to two reasons below:

First, in step (iii′) (group partitioning), the algorithm uses the approximating instantaneous SED rule to mimic the exact rule in (40)-(41). The minimum of the objective function in (50a) is equal to the difference |π₀(y^{t-1})−π₁(y^{t-1})| between the group priors of the partition { [symbol] (y^{t-1})}_{x∈{0,1}} obtained by the approximating rule in step (iii′). The difference is upper bounded as

|π₀(y^{t-1})−π₁(y^{t-1})|≤ [symbol] (y^{t-1}), (51)

where [symbol] is the last type moved to [symbol] (y^{t-1}) so that its group prior exceeds 0.5 for the first time. If |π₀(y^{t-1})≥π₁(y^{t-1}), (51) recovers (41) since [symbol] (y^{t-1}) is the smallest prior in [symbol] (y^{t-1}), thus the approximating instantaneous SED rule recovers the exact rule. If |π₀(y^{t-1})<π₁(y^{t-1}), [symbol] (y^{t-1}) on the right side of (51) is the largest prior in [symbol] (y^{t-1}), violating the right side of (41).

In a number of embodiments, an approximating algorithm of the instantaneous SED rule (40)-(41) is used since it is unclear how to implement the exact instantaneous SED rule with polynomial complexity. in the worst case, the complexity of the latter is as high as double exponential O(2^{q}^{^{N(t)}}) due to solving a minimization problem via an exhaustive search.

Second, in step (vi′) (decoding at time t) of the type-based anytime instantaneous SED code, the algorithm only finds the most likely length-k prefix in the type that achieves maxi [symbol] (y^{t-1}), yet it is possible that this prefix is not the one that has the globa:lfy Largest posterior (43). To search for the most probable length-k prefix, one needs to compute the posteriors for all q^{k} prefixes of length k using O(t) types; resulting in an exponential complexity O(q^{k}t) in the length of the prefix k, whereas the complexity of step (vi′) is only O(t) independent of k.

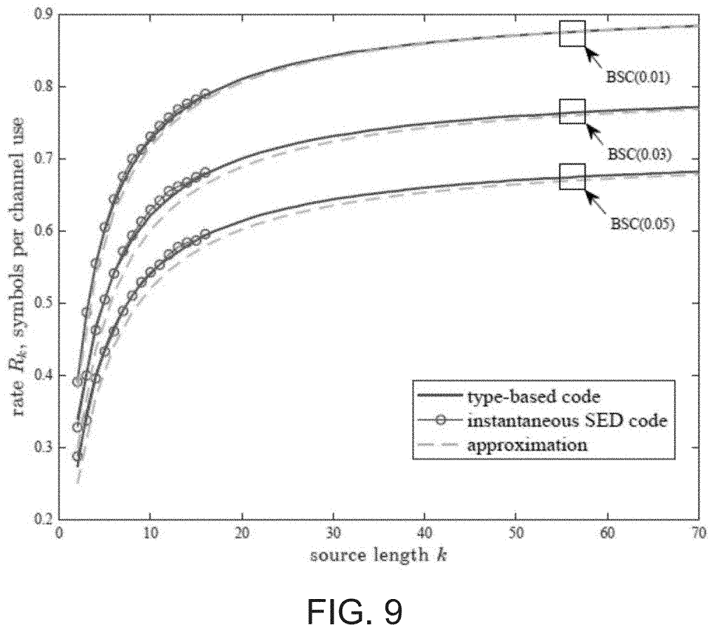

Although the type-based instantaneous SED code is an approximation; as shown in FIG. 9 (discussed below), it is almost as good as the exact code. As can readily be appreciated, the specific instantaneous encoding approach that is utilized is largely dependent upon the requirements of a particular application.

### Simulations

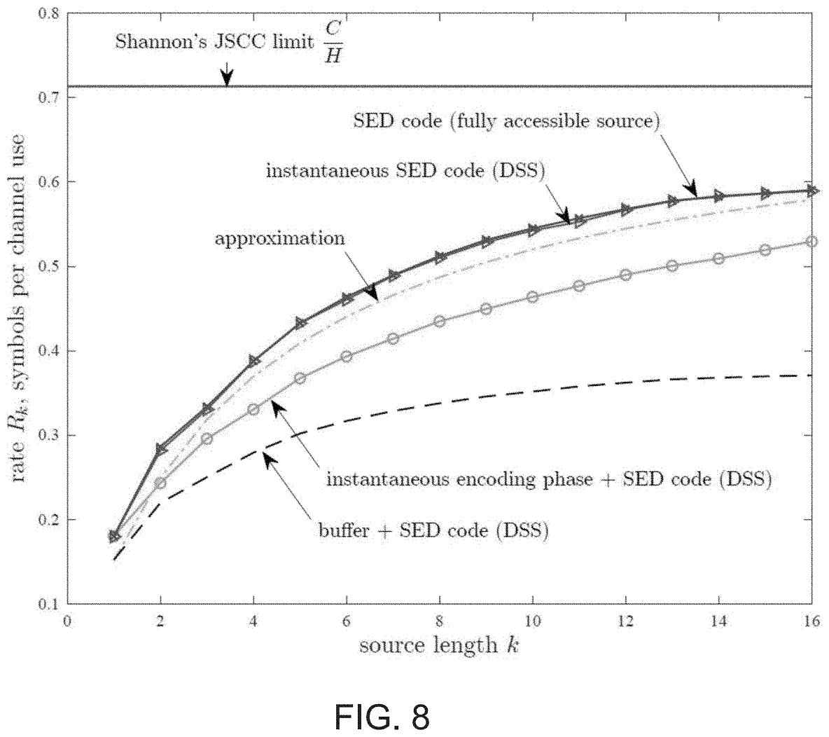

FIG. 8 shows the performance of a number of instantaneous encoding schemes in accordance with various embodiments of the invention. Namely, an error probability ϵ=10⁻⁶, a BSC(0.05) is fixed for a DSS that emits i.i.d. Bernotilli(½) bits one by one at consecutive times. The rate

$${R}_{k} {=}^{Δ} \frac{k}{𝔼 [ {η}_{k} ]}$$

is displayed as a function of source length k empirically attained by the instantaneous encoding phase followed by the SED code and the instantaneous SEP code described above; and achievable rates are compared to that of the SEP code for a fully accessible source; as well as to that of a buffer-then-transmit code that implements the SED code during the block encoding phase. We also plot the rate Rₖ obtained from the reliability function approximation (17):

$$E ( {R}_{k} ) ≃ \frac{{R}_{k}}{k} log \frac{1}{ϵ} . \qquad ( 52 )$$

The instantaneous encoding phase followed either by the MaxEJS code or by the SED code achieves the JSCC reliability function for streaming (36). For the simulations in FIG. 8, the SED code is chosen since it applies to a BSC and its complexity, exponential in the source length, is lower than the double-exponential complexity of the MaxEJS code. To obtain the empirical rate in FIG. 8, at each source length k, the experiments are run fPr every code for 10⁵ trials to obtain the denominator [symbol] [ηₖ] of the empirical rate by averaging the stopping times in all the experiments.

It can be observed from FIG. 8 that the achievable rate of the instantaneous encoding phase followed by the SED code is significantly larger than that of the buffer-then-transmn code, and approaches that of the SED code as k increases even though the SED encoder knows the entire source sequence before the transmission. The instantaneous SED code demonstrates an even better performance: it is essentially as good as the SED code.

The rate obtained from reliability function approximation (52) is remarkably close to the empirical achievable rates of our codes with instantaneous encoding even for very short source length k≃16. For example, at k=16, the rate obtained from approximation (52) is 0.58 (symbols per channel use) and the empirical rate of the instantaneous SED code is 0.59 (symbols per channel rase). This means that the reliability function (17), an inherently asymptotic notion, accurately reflects the delay-reliability tradeoffs attained by the JSCC reliability function-achieving codes in the ultra-short blocklength regime. The achievable rate corresponding to the buffer-then-transmit code is limited by (37).

FIG. 9 shows the performance of the type-based instantaneous SED code. An error probability of ϵ=10⁻⁶ (15) can be a BSC (p) with p=0.05, 0.03, 0.01, and a DSS that emits i.i.d. Bernoulli(½) bits one by one at consecutive times. Rate

$${R}_{k} = \frac{k}{𝔼 [ {η}_{k} ]}$$

is plotted as a function of source length k empirically achieved by the instantaneous SED code described above and its corresponding type-based code, as well as the rate obtained from the reliability function approximation (52). At each source length k, experiments are run using the same method as in FIG. 8. The rate gap between the instantaneous SED code and the type-based instantaneous SED code is negligible, meaning that the type-based instantaneous SED code with only log-linear complexity is a good approximation to the exact code. Irthermore, it is interesting to see that even though the DSS has symbol arriving rate f=1 symbol per channel use, which is far less than that required in assumption (b′), the achievable rates of the instantaneous SED code stay very close to the rates obtained from the reliability function approximation. This suggests that assumption (b′) on the symbol arriving rate, sufficient for the instantaneous SED code to achieve E(R), could be conservative.

### Streaming Over a Degenerate DMC With Zero Error

Systems and methods in accordance with several embodiments of the invention utilize a code with instantaneous encoding over a degenerate DMC (9) that achieves zero decoding error at any rate asymptotically below C/H. In several embodiments, the code allows common randomness U∈ [symbol] , which is a random variable that is revealed to the encoder and the decoder before the transmission. With common randomness U, the encoder fₜ (12) can use U to form Xₜ, and the decoder gₜ (13) can use U to decide the stopping time ηₖ and the estimate Ŝ_{η}_{ₖ}^{k}. Such a code can be referred to as a [symbol] k, R, ϵ [symbol] code with instantaneous encoding and common randomness if it achieves rate R (14) and error probability ϵ (15) for transmitting k symbols of a DSS.

In a number of enerbodiments, to achieve Shannon's JSCC limit C/H, a Shannon limit-achieving code is used in the first cc mnunicatiosi phase to compress the source. To transmit streaming sources, an instantaneous encoding phase that satisfies (38) is combined with a Shannon limit-achieving block encoding scheme to form a Shannon limit-achieving instantaneous encoding scheme. To achieve zero error, confirmation phases can be employed. It can be said that a [symbol] k, R, ϵₖ [symbol] code with instantaneous encoding and common randomness C/H achieves Shannon's JSCC limit C/H if for all

$$R < \frac{C}{H} ,$$

a sequence or such codes indexed by k satisfies ϵₖ→0 as k→∞. In a number of embodiments, the zero-error code includes such Shannon limit-achieving codes as a building block. Note that in contrast to the discussions above focused on the exponential rate of decay of ϵₖ to 0 (17) over non-degenerate DMCs, here merely having ϵₖ decrease to 0 suffices.

A joint source-channel code can be employed due o the simplicity of the error analysis it affords. One such code, is a [symbol] k, R, ϵₖ [symbol] Shannon limit-achieving code with block encoding and common randomness because its expected decoding time to attain error probability ϵ is upper bounded with C₁←C, implying that it achieves a positive error exponent that is equal to (36) with C₁←C for all

$$R < \frac{C}{H} .$$

Another suitable block encoding scheme is a stop-feedback code, meaning that the encoder uses channel feedback only to decide whether to stop the transmission but not to form channel inputs. If the DSS has an infinite symbol arriving rate if f=∞ (5), a buffer-then-transmit code using the block encoding scheme can achieve the Shannon limit. the same token, if the DSS has a finite syMbol arriving rate f<∞ (5) a code implementing an instantaneous encoding phase that satisfies (38) followed by any of the suitable block encoding schemes described herein for k source symbols with prior P_{S}^{k}_{Y}^{t}ₖ achieves the Shannon limit.

In certain embodiments, the zero-error code with instantaneous encoding and common randomness for transmitting k symbols over a degenerate DMC operates as follows. In several embodiments, the code is divided into blocks. Each block can contain a communication phase and a confirmation phase. In the first block, the communication phase uses a [symbol] , R, ϵₖ [symbol] Shannon limit-achieving code with instantaneous encoding and common randomness. The confirmation phase can select two symbols x (9a) and x′ (9b) as the channel inputs (i.e., x′ never leads to channel output y); the encoder repeatedly transmits x if the decoder's estimate of the source sequence at the end of the communication phase is correct, and transmits x′ otherwise. If the decoder receives a y in the confirmation phase, meaning that the encoder communicated its knowledge that the decoder's estimate is correct with zero error, then it outputs its estimate, otherwise, the next block is transmitted. The [symbol] -th block, [symbol] ≥2, differs from the first block in that it does not compress the source to avoid errors due to an atypical source realization and in that it uses random coding whereas the first block can employ any Shannon-limit achieving code.

In a number of embodiments, the code achieves zero error by employing confirmation phases that rely on the degenerate nature of the channel: receiving a y in the confirmation phase guarantees a correct estimate.

In certain embodiments, the code achieves all rates asymptotically below C/H because 1) the first block employs a Shannon limit-achieving code in the communication phase, 2) the length of the confirmation phase is made negligible compared to the length of the communication phase as the source length k→∞, meaning that the length of the first block asymptotically equals the length of its communication phase, and 3) subsequent blocks asymptotically do not incur a penalty on as we discuss next. Since the length of each block is comparable to the length of the first block, it is enough to show that the expected number of blocks Tₖ transmitted after the first block converges to zero. The refreshing of a random codebook for all uncompressed source sequences in evei block after the first block can result in the channel output vectors in these subsequent blocks are i.i.d. and are independent of the channel outputs in the first block. Conditioned on Tₖ>0, the i.i.d. vectors give rise to a geometric distribution of Tₖ with failure probability converging to 0, which implies [symbol] [Tₖ]→0 as k→∞.

### Zero-Error Code With Instantaneous Encoding and Common Randomness

In several embodiments, a zero-error code with instantaneous encoding and common randomness is utilized for transmitting k symbols of a DSS over a degenerate DMC. For a degenerate DMC (9), its single-letter transition probability can be denoted by P_{Y|X}: [symbol] → [symbol] and its capacity-achieving distribution can be denoted by P*_{X}. In the following discussion, x in (9a) is relabeled by ACK, and x′ in (9b) are relabeled by NACK. Gallager's error exponent can be denoted E_{G}(P_{Y|X}, R_{c}), where R_{c} is the channel coding rate in nats per channel. Note that the unit of the rates in many of the examples above is symbols per channel use. The rate of the code used in the communication phase of the [symbol] -th block is denoted by R( [symbol] ), and the estimate formed at the end of the communication phase of the [symbol] -th block is denoted Ŝ^{k}( [symbol] )

In several embodiments, the zero-error code is divided into blocks. Each block can contain a communication phase and a confirmation phase. In many embodiments, the first block is different from the blocks after it, since it uses a Shannon limit-achieving code in the communication phase, whereas the blocks after the first block use random coding for all source sequences in alphabet [q]^{k}. We introduce the first block and the [symbol] -th block, [symbol] ≥2, respectively.

The first block can be transmitted according to steps i)-ii) below.
i) Communication phase. The first k symbols S^{k} of the DSS described above is transmitted via, a Shannon limit-achieving co de with instantaneous encoding and common randomness at rate

$$R ( 1 ) < \frac{C}{H}$$

symbols per channel use. At the end of the comunnlication phase, the decoder yields an estimate Ŝ^{k}(l) of the source S^{k} using the channel outputs that it has received in this phase.
ii) Confirmation phase. The encoder knows Ŝ^{k}(l) since it knows the channel outputs through the noiseless feedback. The encoder repeatedly transmits ACK if S^{k}=Ŝ^{k}(l), and transmits NACK if S^{k}≠Ŝ^{k}(l) for nₖ channel uses. We pick nₖ as

nₖ=δk, (53)

where δ∈(0,1) can be made arbitrarily small. At the end of the confirmation phase, if the decoder receives a y, then it terminates the transmission and output Ŝ_{η}_{ₖ}^{k}=Ŝ^{k}(l); otherwise, the encoder transmits the next block.

The [symbol] -th block, [symbol] ≥2, is transmitted according: to steps iii)-iv) below.
iii) Communication phase. For every sequence in the alphabet [q]^{k} of S^{k}, the encoder generates a codeword via random coding according to the capacny-achieving distribution P*_{X} at rate

$$R ( 2 ) < \frac{C}{log q}$$

symbols per channel use. At the end of the communication phase, the maximum likelihood (ML) decoder yields an estimate Ŝ^{k}( [symbol] ) to of the source symbols S^{k} using the channel outputs that it has received in this phase.
iv) Confirmation phase. The encoder, the decoder, and the stopping rule are the same as those in the first block with Ŝ^{k}(l)←Ŝ^{k}( [symbol] ).

The random codebook is refreshed in every retransmitted block and is known by, the decoder. This gives rise to the following observations:

1) The codewords transmitted in the communication phases of the [symbol] =1, 2, . . . blocks are independent from each other;

2) As a result of the channel outputs of the [symbol] =1, 2, . . . blocks are independent from each other;
3) The codewords transmitted in the communication phase of the [symbol] =2, 3, . . . blocks are i.i.d. random vectors. (The codeword in the first plock is excluded since the first block need not use random coding in the communication phase);
4) As a result of 3), the channel outputs of the [symbol] =2, 3, . . . blocks are i.i.d. random vectors.

While specific zero-error codes are described above for use with instantaneous encoding and common randomness, any of a variety of zero-error codes can be utilized to perform instantaneous encoding as appropriate to the requirements of specific applications in accordance with various embodiments of the invention.

Although the present invention has been described in certain specific aspects, many additional modifications and variations would be apparent to those skilled in the art. It is therefore to be understood that the present invention can be practiced otherwise than specifically described including using any of a variety of different encoders, decoders and streaming (and non-streaming) sources without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. A real-time feedback communication system, comprising:
an encoder configured to:
receive a plurality of symbols from a streaming source;
perform an instantaneous encoding of each s-rubol in the plurality of symbols to generate channel inputs, vhere the instantaneous encoding of each symbol in the plurality of symbols occurs before the arrival of the next symbol in the plurality of symbols;
transmit the generated channel inputs via a communication channel;
receive feedback with respect to each transmission; and
determine source posteriors in response to the feedback received with respect to each transmission;
wherein performing the instantaneous encoding of each symbol in the plurality of symbols comprises:
calculating source priors based upon feedback received with respect to a last transmission, where the source priors calculated by the encoder are calculated for all possible symbol sequences using a source distribution and the posteriors determined by the encoder in response to feedback received by the encoder with respect to the last transmission;
partitioning a message alphabet into groups using a partitioning: rule based upon the source priors calculated by the encoder;
determining an index of one of the groups that contains a sequence corresponding to symbols from the plurality of symbols that have been received by the encoder up to that point in time;
forming a channel input based upon the determined index; and
a receiver configured to:
receive channel outputs via the channel;
transmit feedback in response to the received channel outputs;
decode message symbols based upon the received channel outputs;
wherein decoding each received message symbol comprises:
before receiving a next channel output, calculating source priors based upon at least one previously received channel output, where the source priors calculated by the decoder are calculated for all possible symbol sequences using the source distribution and source posteriors determined by the decoder;
partitioning the message alphabet into groups using the partitioning rule based upon the source priors calculated by the decoder;
upon receipt of the next channel output, calculating updated source posteriors for all possible sequences of source symbols using the source priors calculated by the decoder and the next channel output;
decoding a next received message symbol based upon the next channel output and the groups obt aimed by the decoder using the partitioning rule; and
forming feedback for transmission to the encoder.

2. The system of claim 1, wherein forming a channel input based upon the determined index of the group that contains the sequence corresponding to the symbols from the plurality of symbols received by the encoder up to that point in time comprises applying randomization to match a distribution formed based upon transmitted indexes to a capacity-achieving distribution.

3. The system of claim 1, wherein each generated channel input is independent of past channel outputs.

4. The system of claim 1, wherein the channel is a discrete memoryless channel.

5. The system of claim 1, wherein the channel is a degenerate discrete memoryless channel.

6. The system of claim 1, wherein the partitioning rule partitions the message alphabet into groups so that the source priors of the groups satisfy a predetermined criterion based upon a known capacity-achieving distribution.

7. The system of claim 6, wherein the predetermined criterion minimizes a difference between the source priors of the groups and the known capacity-achieving distribution.

8. The system of claim 6, wherein the predetermined criterion causes the source priors of the groups to be within a predetermined threshold of the known capacity-achieving distribution.

9. The system of claim 1, wherein partitioning, by the encoder, of the message alphabet into groups using the partitioning rule based upon the calculated priors comprises partitioning the message alphabet using a greedy heuristic algorithm.

10. The system of claim 1, wherein the partitioning rule is a type-based group partitioning rule that partitions the message alphabet based on types.

11. The system of claim 1, wherein decoding the message symbols from the channel outputs received via the channel further comprises using the partitioned groups to construct two sets by comparing the source priors of the groups with a known capacity-achieving distribution.

12. The system of claim 11, wherein decoding the message symbols from the channel outputs received via the channel further comprises determining probabilities for randomizing the channel output based upon the two sets.

13. The system of claim 1, wherein each of the plurality of symbols is a data packet.

14. The system of claim 1, wherein the decoder is further configured to learn a symbol arriving distribution online using past symbol arrival times.

15. The system of claim 1, wherein the source is a linear system and the decoder is part of a control system that is configured to provide control signals to the linear system.

16. The system of claim 1, wherein the encoder and the decoder utilize a common source of randomness that is used by the encoder to generate the channel inputs and by the decoder to decode message symbols.

17. The system of claim 1, wherein the encoder is further configured to transmit the channel input formed based upon the determined index prior to the receipt of the next message symbol from the plurality of symbols by the encoder front the streaming source.

18. The system of claim 1, wherein the message alphabet is an evolving message alphabet.

19. An encoder capable of use in a real-time feedback communication system, wherein the encoder is configured to:
receive a plurality of symbols from a streaming source;
perform an instantaneous encoding of each symbol in the plurality of symbols to generate channel inputs, where the instantaneous encoding of each symbol in the plurality of symbols occurs before the arrival of the next symbol in the plurality of symbols;
transmit the generated channel inputs via a communication channel;
receive feedback with respect to each transmission; and
determine source posteriors in response to the feedback received with respect each transmission;
wherein performing the instantaneous encoding of each symbol in the plurality of symbols comprises:
calculating source priors based upon feedback received with respect to a last transmission, where the source priors are calculated for all possible symbol sequences using a source distribution and the posteriors determined by the encoder in response to feedback received by the encoder with respect to the last transmission;
partitioning a message alphabet into groups using a partitioning rule based upon the source priors:
determining an index of one of the groups that contains a sequence corresponding to symbols from the plurality of symbols that have been received by the encoder up to that point in time;
forming a channel input based upon the determined index.

20. The encoder of claim 19, wherein the partitioning rule partitions the message alphabet into groups so that the priors of the groups satisfy a predetermined criterion based upon a known capacity-achieving distribution.

21. A decoder capable of use in a real-tune feedback conununication system, wherein the decoder is configured to:
receive channel outputs via a channel;
transmit feedback in response to the received channel outputs;
decode message symbols based upon the received channel outputs;
wherein decoding each received message symbol comprises:
before receiving a next channel output, calculating source priors based upon at least one previously received channel output, where the source priors are calculated for all possible symbol sequences using the source distribution and source posteriors determined by the decoder;
partitioning the message alphabet into groups using a partitioning rule based upon the source priors;
upon receipt of the next channel output, calculating updated source posteriors for all possible sequences of source symbols using the source priors and the next channel output;
decoding a next received message symbol based upon the next channel output and the groups obtained by the decoder using the partitioning rule; and
forming feedback for transmission.

22. The decoder of claim 21, wherein the partitioning rule partitions the message alphabet into groups so that the priors of the groups satisfy a predetermined criterion based upon a known capacity-achieving distribution.
